(19) United States
(12) Patent Application Publication
(10) Pub. No.: US 2006/0239312 A1
(43) Pub. Date: Oct. 26, 2006

(54) Semiconductor Lasers in Optical Phase-Locked Loops

(75) Inventors: Anthony Kewitsch, Santa Monica, CA (US); George Rakuljic, Santa Monica, CA (US); Amnon Yariv, Santa Monica, CA (US)

Correspondence Address: Anthony Kewitsch, 2118 Wilshire Blvd. #238, Santa Monica, CA, 90403, US

(73) Assignee: Telaris Inc., Santa Monica, CA (US)

(21) Appl. No.: 11/379,409

(22) Filed: Apr. 20, 2006

Related U.S. Application Data
(60) Provisional application No. 60/674,093, filed on Apr. 23, 2005.
(60) Provisional application No. 60/692,853, filed on Jun. 22, 2005.
(60) Provisional application No. 60/776,773, filed on Feb. 24, 2006.

(51) Int. Cl. H01S 3/13; H01S 3/00; H01S 5/00

(52) U.S. Cl. 372/29.023; 372/50.12; 372/38.01; 372/38.02; 372/29.016

(57) ABSTRACT

This invention relates to opto-electronic systems using semiconductor lasers driven by feedback control circuits that control the laser's optical phase and frequency. Feedback control provides a means for coherent phased laser array operation and reduced phase noise. Systems and methods to coherently combine a multiplicity of lasers driven to provide high power coherent outputs with tailored spectral and wavefront characteristics are disclosed. Systems of improving the phase noise characteristics of one or more semiconductor lasers are further disclosed.

### REFERENCE TO RELATED APPLICATIONS

This application relies for priority on provisional application 60/674,093 of Yariv et al., filed on Mar. 23, 2005 and entitled “Optical phase-locked loops,” on provisional application 60/692,853 of Kewitsch et al., filed on Jun. 22, 2005 and entitled “Mode-locked semiconductor laser array,” and on provisional application 60/776,773 of Kewitsch et al., filed on Feb. 24, 2006 and entitled “Arrayed semiconductor lasers in optical phase-locked loops.”

### FIELD OF THE INVENTION

This invention relates to opto-electronic systems using semiconductor lasers driven by feedback control circuits which control the laser's optical phase and frequency. Feedback control provides a means for coherent phased array operation and reduced phase noise.

### BACKGROUND OF THE INVENTION

The optical analogs of electronic components such as amplifiers and filters have undergone significant advances with the development of wavelength division multiplexed optical communications systems. However, several important electronic components, namely the voltage controlled oscillator (VCO) or current controlled oscillator (CCO), do not have high performance optical equivalents. A high performance optical VCO/CCO has the potential to play a key role in future optoelectronic systems, comparable to the role of its radio frequency (RF) counterpart in phased-array radar systems.

The optical CCO functionality can be realized in a primitive fashion by use of a standard semiconductor distributed feedback (DFB) laser. The “FM” or frequency modulation response of the DFB laser has the potential to provide extremely high bandwidths in excess of 20 GHz. However, the frequency of semiconductor lasers depends in a relatively complex way on the level of injection current and these lasers exhibit the potential for frequency mode-hopping, phase inversion and hysteresis. Typically, the FM response or CCO gain is highly frequency dependent and exhibits a 180 degree phase reversal for modulation frequencies in the vicinity of 1 MHz. The phase reversal occurs when the modulation frequency is sufficiently high that the out-of-phase thermal FM response dominant at low frequencies vanishes, leaving only the in-phase electronic contribution. The competition between thermal tuning and electronic plasma tuning is known to be a significant barrier to designing a fundamentally stable, high bandwidth optical phase-locked loop (OPLL).

For the laser LO to precisely track the phase of the reference oscillator (RO), while overcoming the LO's intrinsic phase noise, it is known in the art that the OPLL circuit bandwidth should be designed to provide ten to a hundred times the resulting LO/RO beat note linewidth. To provide this relatively large bandwidth with low phase lag, the physical delay of the OPLL (both optical and electrical) is typically no more than the 1/10 of the inverse bandwidth of the circuit. This is typically a challenging condition to satisfy because of the need for high speed and compact circuitry exhibiting low time delay.

The optical performance of an OPLL system is typically quantified by calculating the residual rms phase error between the local oscillator laser and the reference laser. The rms phase error resulting in 95% coherent power combining is 0.4 rad. For typical laser linewidths of 10 MHz, this requires at least 100 MHz of loop bandwidth. Standard, commercially available DFB lasers do not typically exhibit a well-behaved FM response for frequencies from dc up to 100's of MHz.

A two-section distributed feedback (DFB) laser can be designed to produce an FM response with relatively constant amplitude and phase from dc frequencies up to several GHz. These two section DFB's are typically designed to maximize their tuning coefficient or “CCO gain” to levels in excess of several GHz/mA so that their electronic tuning response overwhelms their thermal response. Alternately, they can be designed to null out the high frequency FM response to produce low parasitic chirp.

The magnitude of the CCO gain directly impacts the OPLL performance. In actual phase-locked loop implementations, it is important to minimize the impact of current noise in the phase-locked loop feedback signal from degrading the laser's spectral purity. Therefore, it is advantageous that a two section laser be designed such that the magnitude of the CCO gain is less than 1 GHz/mA, preferably a few 100's of MHz/mA. Typical two section lasers have significantly larger FM coefficients. In addition, typical two section DFB's provide relatively low optical output powers of a few 10's of mW. For those applications requiring high optical power, new lasers designs are required.

To achieve high optical output power, an array of relatively low power semiconductor laser elements may be used. The practical realization of arrayed semiconductor laser-based OPLLs impose several requirements on the laser: they must be single longitudinal mode/single frequency; the phase of the laser's FM response must be relatively constant over the bandwidth of the feedback control circuit; the laser output power should be greater than or equal to 1 W per emitter; the lasers must be surface emitting; the lasers across the array must be fabricated close in wavelength so they can be tuned to the same optical frequency by changing their bias currents; the laser array layout must allow for compact integration with high speed electronics, and the multi-section laser should be monolithic. At the present time, these multiple and varied laser characteristics have not been realized in a single laser structure, much less an array. In addition, prior art phase-locking approaches have not been compact, integrated nor scaleable, and have not been extended to laser arrays.

### LIST OF FIGURES

FIG. 1 illustrates a system diagram of a coherently combined laser array;

FIG. 2 details an array of vertically emitting, high power MOPA DFB lasers, with (2-A) vertical deflection facet and (2-B) surface deflection grating for outcoupling of beam;

FIG. 3 illustrates a block diagram of an individual OPLL circuit;

FIG. 4 details the hybrid integration of lasers, detectors, and PLL circuits on a vertically emitting array;

FIG. 5 details an example of a laser array system;

FIG. 6 illustrates a perspective view of a stacked, two-dimensional array of one dimensional edge emitter arrays;

FIG. 7 illustrates a coherently combined laser system in which the detector and PLL circuitry are located physically separate from the laser array;

FIG. 8 illustrates a coherently combined laser system utilizing an external optical amplifier to produce high optical power;

FIG. 9 details a beam shaping optical system;

FIG. 10 illustrates the amplitude and phase of a shaped beam (9-A) and the arbitrary control of the spatial variation of phase (9-B);

FIG. 11 details a block diagram of the OPLL for producing mode locked pulses;

FIG. 12 illustrates the comb-like amplitude spectrum from a mode-locked laser array;

FIG. 13 illustrates a wavelength combining optical system which joins multiple laser modes at different center frequencies into a single overlapping and co-propagating output mode;

FIG. 14 illustrates a wavelength combining optical system which combines multiple laser modes at different center frequencies onto a single overlapping spot at a substrate plane;

FIG. 15 is a block diagram of a pair of frequency and phase locked lasers;

FIG. 16 is a block diagram of a laser CCO locked to a reference laser;

FIG. 17 is a block diagram of two laser CCO's locked to the same reference laser;

FIG. 18 is a block diagram of N laser CCO's locked to the same reference laser;

FIG. 19 is a block diagram in which a laser CCO is locked to itself using a frequency discriminator element;

FIG. 20 illustrates a fiber bundle for coherently combining laser outputs;

FIG. 21 is a flow diagram detailing the steps of phase locking for coherent combining, and

FIG. 22 illustrates a feedback control system to achieve aided frequency acquisition and phase locking.

### SUMMARY OF THE INVENTION

In this invention, we disclose phase-locked semiconductor lasers whose optical phase and frequency characteristics are precisely controlled by use of high speed integrated circuits. Potential single frequency semiconductor laser elements include the vertically cavity surface emitting laser (VCSEL) and distributed feedback laser (DFB). For example, an emitter may be comprised of a two section DFB oscillator driven in an asymmetric, push-pull configuration to provide controlled and well-behaved frequency modulation response. The lasers are arranged as individual elements, bars, or two dimensional arrays. In a further example, each DFB laser includes a tapered, electrically pumped optical amplifier section to increase the optical power.

Laser designs which satisfy the unique requirements of phase-locking advantageously provide for high optical power, high electrical efficiency, high beam quality, single temporal and spatial mode output, and constant phase FM response over a bandwith in excess of 100 MHz are disclosed. These design features enable the optical fields of large numbers of lasers to be coherently combined to produce a high brightness semiconductor laser source. In addition, the phase of each laser within an array can be locked to be exactly in-phase with the reference laser or with programmable phase offsets. Electronic frequency and phase-locking is achieved by high-speed integrated electronics that provide both a large electrical bandwidth as well as the control and functionality necessary for stable coherent beam combination. Alternate opto-electronic implementations provide a low noise laser source or a mode-locked pulse train. Implementations to provide beam steering and beam shaping features are also disclosed.

### DETAILED DESCRIPTION OF THE INVENTION

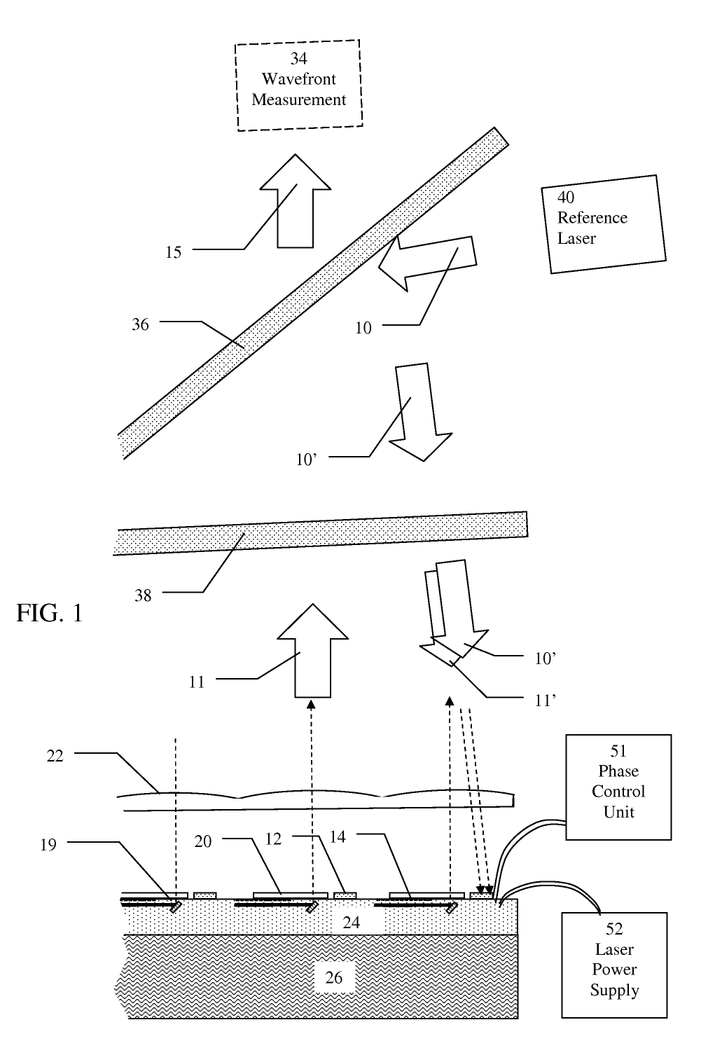

In this invention we disclose techniques for coherent optical beam combining of one or two dimensional semiconductor laser arrays driven by optical phase-locked loops (OPLLs). FIG. 1 illustrates a laser system comprised of a two dimensional array of vertically emitting, single-mode DFB lasers 24. Coherent combining of the laser output beams 1-j, where j denotes a particular emitter, is accomplished by integrating high-speed CMOS or SiGe BiCMOS circuitry 20 with integrated optical detectors 12 to electronically drive the ensemble of laser emitters 14 under conditions of phase and frequency lock. The laser array 24 is powered by an external electrical current supply 52 and backside cooled by use of element 26 in intimate thermal contact. The individual optical output beams 11-j are directed out of the plane of array 24 by individual etched steering mirrors 19. The use of etched mirrors for directing a laser's output normal to the substrate plane has been described by Osowski et al. [“Frequency-Stabilized Surface Emitting Diode Laser Arrays with Monolithic 45 Degree Turning Mirrors”, SSDLTR conference, 2004].

The laser outputs 11 are collimated by a lens array 22 which produces a composite, collimated output field 15 with an effective aperture given by the dimensions of the laser array 24. Each lens of the lithographically patterned GaP micro-lens array is in precise alignment with the corresponding emitter element. The curved surfaces of lens array can be either on the local emitter side or the reference laser side of the optical system, depending on considerations of optical abberation and backreflection management.

Individual OPLL circuits inject current into the laser to modulate the emission frequency to synchronously drive the lasers. A pickoff mirror 38 reflects a small fraction (˜0.1%) of each laser's output 11′ back onto its photodetector 12. A reference laser 40 with output 10 is directed by a beamsplitter 36 to be colinear with the reflected outputs 11′. The lens array 22 then focuses the colinear reference output 10′ into individual spots which overlap with beams 11′ and optically mix in each photodetector 12. This electrical mixing signal serves as the input to the electronic feedback control circuit.

Each OPLL circuit receives a phase control input produced by controller 51. The individual phase control inputs set the relative phases of each laser emitter 14. The phase control can be programmed to give a target waveform based on real time measurements from a wavefront measurement apparatus 34, for example. In one implementation, this waveform can be set to provide a diffraction limited output by maximizing the optical power passing through a diffraction limited aperture. Additionally, the relative phase of each laser element may be updated at a high rate to provide adaptive wavefront control.

More specifically, the phase control unit 51 utilizes one or more detector arrays, such as a charge coupled detector (CCD) or CMOS detector, to measure the intensity profile at one or more locations along the beam. For example, unit 51 may include a shearing interferometer or a Shack-Hartmann type interferometer, which uses a lens array to transform phase variations to position variations of focused wavefront elements on the two dimensional detector array. Alternately, an aperture followed by a photodetector can be utilized to provide a measure of “times diffraction limited” by determining the power-in-the-bucket. The phase control unit 51 includes electronic signal processing and digital logic to translate these measurements into an optimal set of phase control outputs for each laser element. For example, the phase of each laser element is dithered at a particular frequency and its effect on the composite wavefront identified by extracting that frequency component from the wavefront measurement.

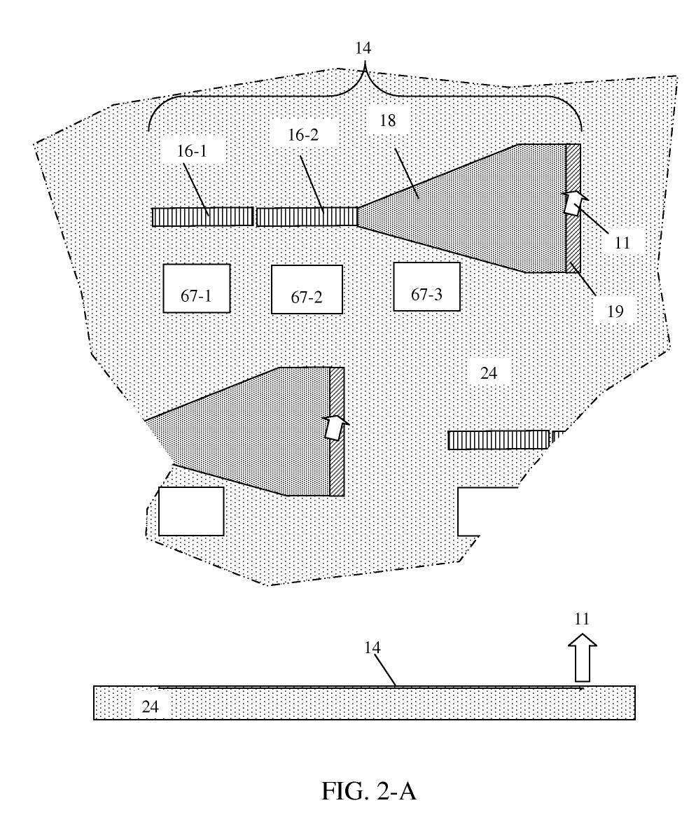

FIG. 2-A details the top view of the laser array substrate 24. In a particular implementation, each laser element 14 consists of a diode laser with one or more DFB sections 16-1, 16-2 emitting 100 to 200 mW of optical power at a single frequency with a phase noise spectrum characterized by a <10 MHz width. This optical power is input into an electrically pumped, monolithically integrated optical amplifier section 18. The amplifier 18 increases the spectrally pure DFB laser output power to the 1-5 W level. A MOPA laser with a single DFB section for high power applications has been described, for example, by R. M. Lammert [“High Brightness InAlGaAs Laser Diode Bars with Tapered Emitters”, SSDLRT conference, 2005]. The output of the amplifier section ends with an etched steering mirror 19 that directs the high power optical output 11 out of the plane of laser array 24.

Alternately, in FIG. 2-B the output of the optical amplifier 18 launches light into a region of the substrate containing a surface deflection grating 19′, which not only redirects the beam out of the plane of the substrate but also to potentially provide focusing power for collimation purposes or to correct for beam astigmatism. FIG. 2-B illustrates curved grating profiles etched into the surface of the laser substrate.

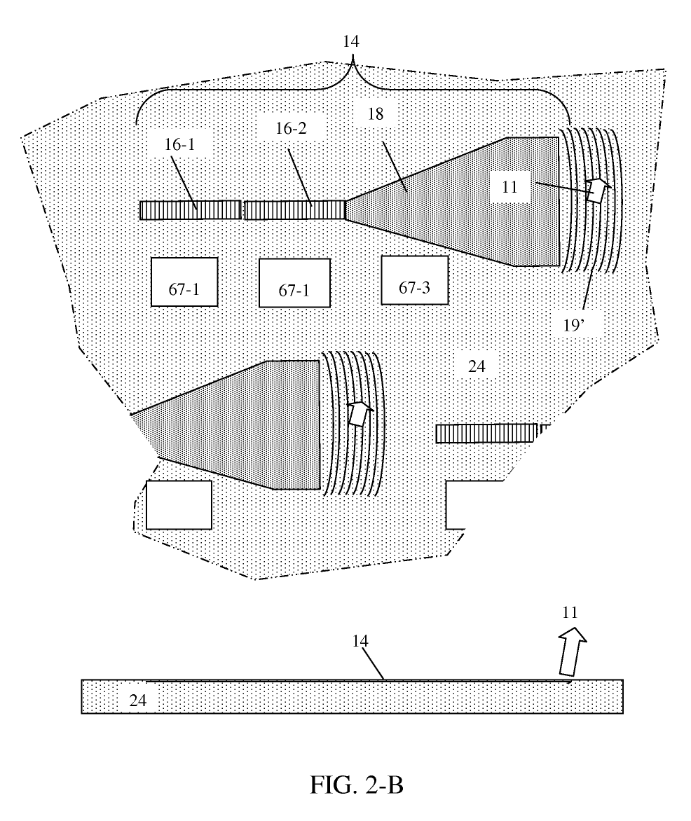

FIG. 3 illustrates a block diagram of an individual OPLL circuit including a reference laser (RO) 40 and a local oscillator (LO) laser 14. The RO and LO optical fields are combined by the beamsplitter 26, mixed in the photodiode 12 and amplified by a transimpedance amplifier (TIA) 55, producing a beat note centered on the RO-LO difference frequency. In the case of offset locking, in which the RO and LO are locked to within a fixed frequency offset, this beat note is input into a mixer 57 (or alternately a phase/frequency detector) and driven by rf oscillator 50 which forces the two lasers to have a precise difference frequency under locked conditions. The difference frequency is equal to the frequency of rf oscillator 50. In some cases, a frequency divider is disposed after the transimpedence amplifier 55 to reduce the bandwidth requirements of the downstream circuit.

The output of the mixer 57 is a baseband signal which is input into loop filter 58, for example, a passive lead/lag type with a pole and zero to provide a second order PLL response. A phase/frequency detector may be used in lieu of the mixer. Phase locked loops are characterized as first order, second order, or third order, based on the number of integrators in the loop. It is further advantageous for this loop filter to include an electronic integrator which holds the laser bias current necessary to maintain locking under thermal drift, for example. In this case, the PLL circuit is third order.

The OPLL circuit advantageously includes an acquisition function 53 which sweeps the LO laser frequency until a beam note within the bandwidth of the photodiode 12 is detected. The acquisition circuit tunes the bias current at 52-1, using a search algorithm based on stepping through or ramping the current, for example, until the baseband beat note is detected within the loop bandwidth of the OPLL.

The output of the loop filter 58 is summed with the dc bias current and input to the gain section of a local oscillator. In a particular example, the output of the loop filter 58 is input into a current amplifier 56 which is summed with bias currents 52-1 and 52-2 and injected into the two oscillator sections 16-1 and 16-2 of laser element 14. The feedback current signals are split into two paths, one of which is summed with the section 2 bias current and injected into section 2, and the other which is input into an inverting gain stage 54 to provide the proper ratio of modulation currents, summed with the section 1 bias current and injected into section 1. A constant current supplied by source 52-3 drives the MOPA laser amplifier section 18. The physical size of the actual circuit and the resulting time delay through the feedback loop is preferably kept as small as possible (i.e., below 1 ns) to enable a feedback loop bandwidth of about 100 MHz.

Example: Hybrid Integration of PLL Circuitry with Laser Array

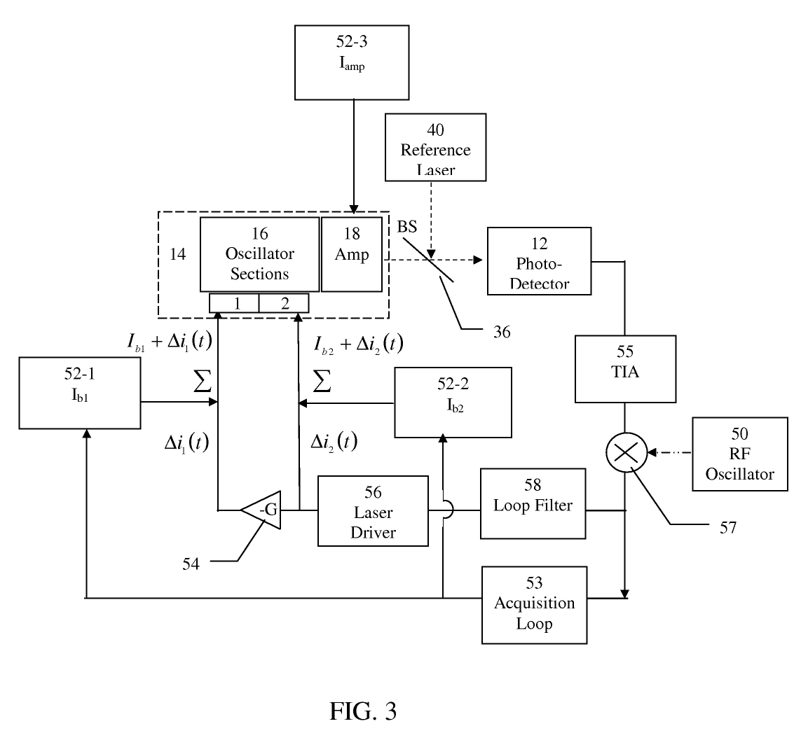

FIG. 4 details a laser array system comprised of lasers 14, detectors 12 and PLL circuits 20 distributed and electrically integrated on the surface of a vertically emitting laser array 24 substrate. The laser array includes individual CMOS or BiCMOS circuit die 20 and InGaAs detector die 12 which are die attached and wire bonded to the laser substrate or a flexicircuit carrier patterned to allow laser emission to pass through, using, for example, automatic chip shooters, pick-and-place machines and wire bonders. The use of unpackaged die enable compact electronic integration with low loop delay. Each circuit die 20 may include the circuitry to drive more than one emitter element; for example, to drive four nearest neighbors. The laser array substrate or flexicircuit carrier is additionally patterned with a series of electrical conductors serving as buses providing the drive current (typically 2 to 4 amps) for the series arrangement of amplifier sections and the drive currents (typically 400 mA to 700 mA total current) for the two DFB sections. In the particular example illustrated in FIG. 4, bus 61 supplies the laser amplifier drive current, bus 63 supplies the laser oscillator drive current, bus 60 supplies the ground, and bus 62 supplies the individual phase control voltages for each emitter. The phase control voltage signal can be potentially time multiplexed on a single conductor for slow update rates (for example, 100's KHz).

The emitters are densely packed with adjacent rows of emitters offset from one another, with the ratio of their x and y spacings nominally equal to the laser beam x and y divergence angles. By use of a collimating lens array and Fourier filtering optics above this laser plane, the MOPA outputs form a single, coherent beam of high spectral and spatial purity. The outputs 11 of the in-plane lasers are directed out-of-plane by use of well known fabrication processes that selectively etch deflection mirrors 19 at precise and consistent angles along a crystallographic plane. This produces identical beam deflection angles for all emitters in the array. Alternately, a diffraction grating based output coupler 19′ may be used to direct the laser output 11 out of the plane of the substrate and also to potentially focus the beam for collimation and/or to correct for beam astigmatism.

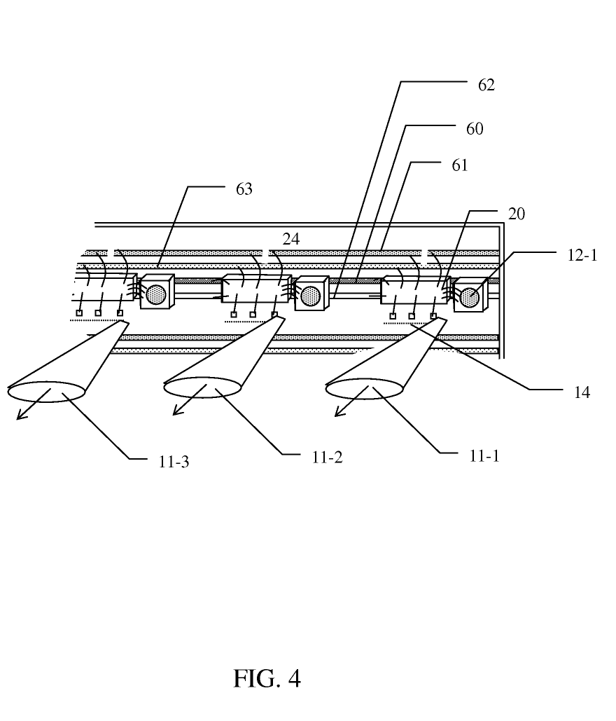

The laser array requires an external optical system to achieve coherent aperture filling and distribution of a portion of the reference laser beam onto each photodetector. Such an integrated laser system is illustrated in FIG. 5. The laser array substrate 24 is in intimate contact with a backside cooler 26 to dissipate the excess heat resulting from the 50% to 85% electrical efficiency of the laser diode elements 14. On the laser array front surface, BiCMOS or CMOS circuitry based on a process with 180 nm or 130 nm feature size, for example, and InGaAs photodetectors are distributed as illustrated in FIG. 4. A polarizer 35 is placed in front of the photodetectors 12 to ensure that spurious backreflections and scatter of the LO outputs do not interfere with the LO-RO mixing signal at each detector. The polarizer's transmission axis is perpendicular to the polarization direction at the output of each laser 14. To enable the laser output 11 to pass through the polarizer 35, the polarizer 35 is patterned to provide open apertures through which the laser outputs 11 can pass unperturbed. A microbaffle array 39 placed in front of the polarizer 35 prevents optical leakage or crosstalk from one OPLL to the adjacent OPLL's. The microbaffle is, for example, a metallic or plastic substrate with a periodic sequence of apertures properly sized and oriented to allow output beam 11-j to be transmitted from the laser 14-j and to allow the reflected output beam 11-j′ to be received by its associated photodetector 12-j, while eliminating the leakage of beam 11-i (i not equal to j) from being detected at photodetector 12-j.

To collimate the arrayed emitter outputs 11-1, . . . 11-N into a single output beam, a diffraction-limited lens array 22 fabricated of GaP or an equivalent high index of refraction and low optical absorption material is utilized. Dead zones between lenses resulting from fabrication limits are typically 100 microns or less and result in an over 90% effective fill factor. Lenslet array 22 focusing elements are preferably interleaved in an A-B-A-B-A-B pattern to maximize the packing density. Microlens arrays may use toric surfaces to simultaneously collimate both axes simultaneously (as illustrated in FIG. 5), separate arrays of fast and slow axis collimators, or a combination of a surface deflection grating (FIG. 2-B) and a lens array. The lens array 24 is followed by a quarter waveplate 37-1, wedged pickoff mirror 38, and quarter waveplate 37-2 combination. While these optics are tilted to prevent backreflections from coupling back into the laser emitters, the pickoff mirror 38 is nearly normal to the emitter outputs and is coated to produce a slight (˜0.1%) backreflection which returns through the first quarter waveplate 37-1 such that the polarization of this reflection is orthogonal to the polarization of the laser output 11. This controlled reflection is focused to a spot offset from the front facet of the laser emitter output such that it falls directly on the active area 12-1 of the detector. The majority of laser output power (>99%) passes through the pickoff mirror and through the second quarter waveplate 37-2, whose optical axis is oriented at 90 degrees relative to the first quarter waveplate 37-1. This transmitted beam experiences no net polarization rotation and minimal insertion loss.

The use of quarter waveplate pairs 37-1, 37-2 rotates the polarization of reflected local oscillator output 11′ to prevent extraneous optical feedback from coupling back into the local oscillator 14. The baffle array 39 further prevents optical crosstalk between adjacent emitters 11-i and 11-j, where j is not equal to i. A polarization beam splitter 36 is placed behind the lens array 22, to couple the reference laser 40 back through the optical system and direct a fraction of it onto each OPLL's photodiode 12. The angle of the RO beam 10′ is selected such that it is aligned with each detector 12 and LO optical beam 11′-j to produce a mixing signal with high contrast.

The reference laser 40 is directed in a counter-propagating sense through the common optical system and its output beam 10 is polarized orthogonal to the local oscillator outputs 11, preventing optical injection locking of the reference laser into the local oscillator lasers. The reference laser 40 is distributed onto each OPLL detector 12 by first passing through a beam expander 41 to increase the reference laser output beam diameter such that the entire laser array 24 aperture will be filled. The reference laser output 10 is polarized orthogonal (p) to the laser array output 11 (s) and a polarization beam combiner 36 allows the reference beam 10′ to propagate back through the lens array system and also to efficiently out-couple the laser array combined output 15, without experiencing significant insertion loss. To prevent undesired optical interactions between the laser array and the reference laser, an optical isolator 44 is placed immediately in front of the reference laser.

This coherent laser array system has several design features to promote stable, phase-locked operation: (1) the polarizer 35 in front of detectors suppresses mixing noise arising from stray reflections and scattered light; (2) tilting of optics so their surface normal is not coincident with beam propagation directions prevents back reflections from coupling back into lasers; (3) the micro baffle array 39 blocks-out optical crosstalk between adjacent emitters; (4) electronic filtering rejects unwanted beat signals arising from adjacent emitters; (5) the use of quarter wave plates 37-1, 37-2 and polarizer 35 allows a well controlled LO signal to be directed back to each OPLL, and (6) the isolator 44 in front of the reference laser 40 prevents LO outputs from being coupled back into the RO.

In a further example, the total reference laser power is 1 W uniform across the laser array aperture. For an array of five thousand 2.5 W lasers, approximately 0.1 mW of reference power falls onto each local detector. In addition, a fraction of each laser emitter's output power is simultaneously reflected back onto each local detector.

By operating the laser array with the acquisition loop activated, the optical outputs of an array of vertically emitting, high-power single-mode DFB-MOPA lasers are independently tuned until their frequencies lies within the locking range of the circuit (typically 100's of MHz to 10's of GHz), after which the phase lock control is activated and the laser frequencies are rapidly pulled-in and locked to the common reference laser. All laser elements 14 are driven electronically such that they are forced into phase synchronism with one another and are mutually phase coherent.

This laser array approach is extendable to systems producing diffraction limited optical output powers of 10-100 kW for large numbers (e.g. thousands) of lasers. In a particular example, the array of single mode, high power (1-5 W), vertically coupled, two section DFB lasers are phase and frequency locked to a single reference laser in the wavelength range of 700 nm to 1600 nm by the use of an array of OPLLs, including integrated GaAs optical detectors and high speed SiGe BiCMOS integrated circuits with critical feature sizes of 90 nm to 250 nm. In a particular implementation, each of the local oscillators are locked to the same rf offset from the reference laser 40, the offset typically in the range of 0.5 to 5 GHz. In this case, an additional rf clock signal (0.5 to 5 GHz) is distributed across the surface of array 24 (not shown in FIG. 4), potentially parallel to the existing ground 60, amplifier current 61, oscillator current 63, and phase control signal 62 buses. Furthermore, the PLL integrated circuit 20 and photodetector 12 may extract their electrical power from the bias currents, or a separate voltage supply bus can be patterned on the surface of the laser array. Electrical buses can also be provided by use of a flexicircuit patterned to interface with and cover the laser array, while having laser or die cut regions allowing the passage of laser optical outputs and inputs. The circuit and photodetector are potentially attached directly to the flexicircuit.

Example: PLL Electronics Physically Separate from Laser Array

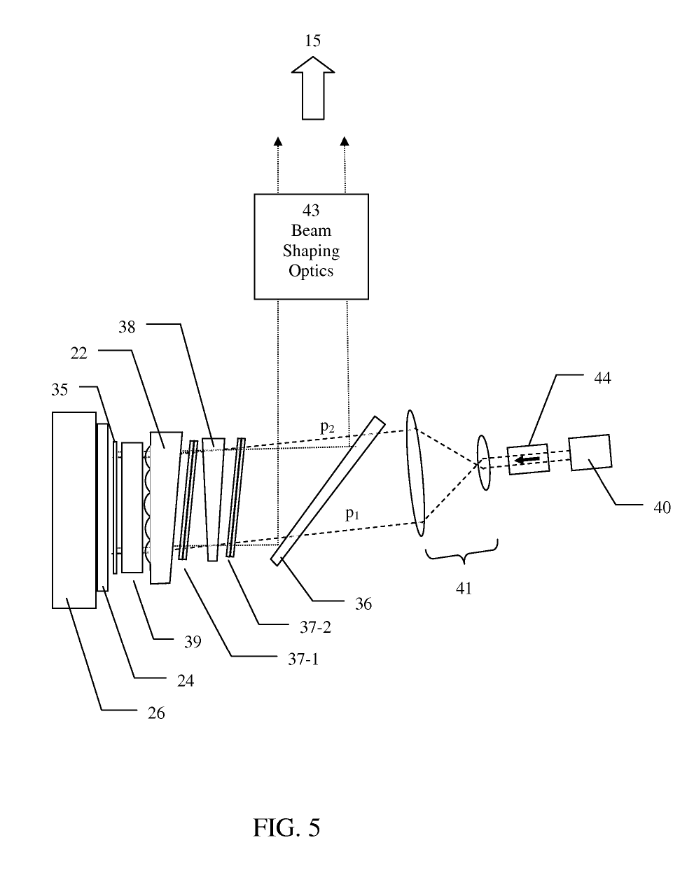

In an alternate embodiment, the electronically phase-locked laser array is comprised of stacked, one dimensional arrays of single mode edge emitters. FIG. 6 illustrates a perspective view of an array using one dimensional edge emitter arrays to produce a hexagonal composite output beam 15 tiled with individual emitters 11. In this implementation it is preferred that narrow linewidth (100's of KHz) DFB emitters are utilized, which relaxes the requirements for feedback loop bandwidth. For loop bandwidths of <10 MHz, the PLL circuit and photodetector elements can be located at a physically separate plane from the laser array, providing additional optomechanical design flexibility.

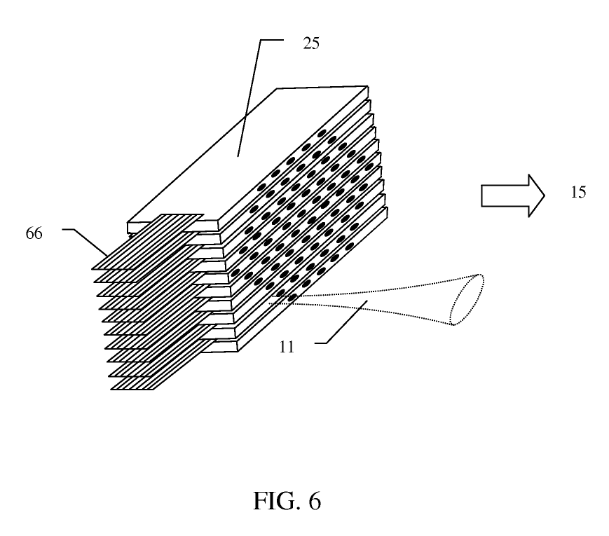

FIG. 7 illustrates a coherently combined laser system diagram in which the detector 12 and PLL circuitry 20 are separately located from the laser array 24. As in earlier examples, the laser array 24 incorporates vertically emitting 2-D arrays or the more common stacked edge-emitters illustrated in FIG. 6. Parallel electrical interconnects 66 interface individual laser emitters 14 with remotely located OPLL circuits 20 and detectors 12. In this configuration, the electronics and/or detectors can be in the form of circuit die attached to a substrate.

Example: Semiconductor Laser Phased Array with External Optical Amplifier

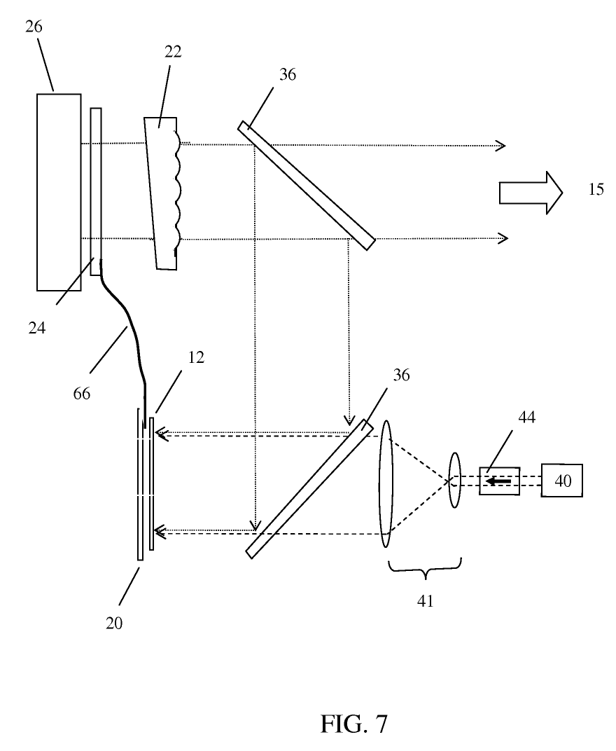

In an alternate embodiment, relatively low power, single frequency VCSEL laser emitters 14′ or DFB lasers 14 are coherently combined by use of electronic feedback. FIG. 8 illustrates the array of VCSEL emitters 14′, wherein emitters are in the form of posts with surrounding material etched away to produce waveguides oriented perpendicular to the substrate plane 24. Typical single frequency VCSEL's produce relatively low power (<10 mW), while typical single frequency DFB lasers provide <100 mW. For many applications, a phased array laser source with 10 to 100 W total output power utilizing 1000's of 10-100 mW emitters is acceptable. However, for systems requiring high power (>100 W), an external amplifier section 99 may be inserted at a location along the path of the output beam(s) 15 or 11 to increase the optical power by typically 10 to 30 dB. The amplifier 99 may utilize a semiconductor (e.g., InGaAs), solid state (e.g., Nd:YAG), or fiber amplifier (e.g., erbium doped silica) gain medium. The semiconductor-based amplifier is typically driven with an injection current or “electrically pumped”, while the solid state and fiber amplifiers are typically optically pumped.

The phase of each emitter 14 or 14′ is controlled by phase control unit 51 to produce an optical phased array source in which the phase of each beam segment corresponding to a particular OPLL element can be programmed arbitrarily and with high speed.

Example: Single Temporal Mode Semiconductor Laser Elements

Electronic phase locking of semiconductor lasers places two fundamental requirements on individual emitter elements. First, the laser should emit at a single frequency or single temporal mode. Typically, the optical power at other frequencies, for example, in spectral sidebands, should be less than 1% of the power in the central peak. Typicaly, semiconductor lasers require a frequency selective element such as a grating to filter out unwanted Fabry-Perot modes. This level of sideband suppression further requires minimization of backreflections to prevent coupling back into the laser cavity, which can produce external cavity effects. A second requirement is that the laser's FM response, or frequency change produced by a given injection current change, exhibits a response with relatively constant phase within the bandwidth of the feedback loop. For example, a laser with a 10 MHz linewidth requires a feedback loop bandwidth of 100 MHz. Over this range, the phase of the FM response should vary by less than 90 degrees. Larger phase variation (greater than 90 degrees) can lead to instability of the feedback control loop in the absence of a suitable electronic phase compensation approach.

Semiconductor laser devices which achieve these dual requirements include distributed feedback lasers (DFB's) and vertically cavity surface emitting lasers (VCSELS). Active phase locking can be accomplished at all potential emission wavelengths by use of a fast photodetector with appropriate responsivity. Typical semiconductor laser wavelengths extend from the visible (400 nm) to the near infrared (1700 nm); however, the approaches disclosed herein are not limited to these wavelengths. Typical semiconductor laser materials are comprised of the class including GaAs, InGaAs, InGaP, GaN, and AlGaAs.

Example: Two Section DFB-MOPAs Emitters with Adaptive FM Response

A laser emitter 14 exhibits a well-behaved “CCO” characteristic if the phase of its FM response is relatively constant within the feedback circuit bandwidth required for stable locking. If the FM response has a strong spatial hole burning component, for example, which is of the same phase as the thermal FM response, then it is possible for DFB emitters 14 with a single section to have a sufficiently constant phase FM response. This may be produced by proper selection of the effective phase and reflectivity of the front and rear reflectors of the DFB emitters. The desired constant phase FM response may be achieved by suppressing the front reflection to a value of less than 10%, for example.

For adaptive electronic control of the FM response, we further disclose herein a laser emitter 14 comprised of a two-section DFB oscillator 16 with an additional, monolithically integrated, tapered optical amplifier section 18. This emitter is utilized as an individual element, as a bar or as a two dimensional array. The resulting two-section DFB-MOPA laser produces both high optical power and electronically programmable FM response with well-behaved optical CCO characteristics, making it suitable for the electronic locking approach disclosed herein.

The design of a DFB oscillator with two independently driven sections adds an additional degree of freedom enabling the FM response of a given device to be electronically varied in magnitude and sign by changing the bias and modulation current ratios across the two sections. The FM response of each emitter is optimized adaptively, for example, by electronic control means. The two oscillator sections are driven in an asymmetric push-pull relationship while the amplifier section is un-modulated. In the asymmetric push-pull approach disclosed herein, the bias or “dc” current densities in the two sections 16-1, 16-2 are made dissimilar. This is achieved by injected the same bias current into the two sections of unequal length, injecting different bias currents into two sections 16-1, 16-2 of equal length, or by injecting different bias currents into different length sections. For example, if the lengths of the two sections are made equal, then the ratio of bias currents adjust the magnitude of the FM coefficient. In this example, the relative amplitudes of the modulation currents applied to each section are determined simply by the ratio of bias currents.

The electronic plasma response of the multi-section DFB laser is estimated by solving the semiconductor laser rate equations. Based on the analysis of Yariv [Opt. Letters Vol. 30 No. 17 (2005) pp. 2191-2193], the induced frequency shift of a semiconductor laser arising from the electronic plasma mechanism is:

$${Δω}_{elec} ( t ) = - \frac{α}{2} ( \frac{1}{{P}_{0}} \frac{ⅆ ( Δ P )}{ⅆ t} + \frac{ɛ}{{τ}_{p}} Δ P ( t ) ) . \qquad ( 1 )$$

For a two-section laser, the equivalent expression is:

$$\begin{matrix}{Δω}_{elec} ( t ) = - \frac{{α}_{1}}{2} {χ}_{1} ( \frac{1}{{P}_{1 , 0}} \frac{ⅆ ( Δ {P}_{1} )}{ⅆ t} + \frac{{ɛ}_{1}}{{τ}_{p}} Δ {P}_{1} ( t ) ) - \\ \frac{{α}_{2}}{2} {χ}_{2} ( \frac{1}{{P}_{2 , 0}} \frac{ⅆ ( Δ {P}_{2} )}{ⅆ t} + \frac{{ɛ}_{2}}{{τ}_{p}} Δ {P}_{2} ( t ) ) ,\end{matrix} \qquad ( 2 )$$

where the photon density is Pⱼ(t) for section j. Note that χ₁+χ₂=1, where χ₁, χ₂ are the length fractions of sections 1 and 2, respectively. τₚ is the photon lifetime at transparency, e is the electron charge, αⱼ is the linewidth enhancement factor and εⱼ is the gain suppression factor. Typical laser parameter values are listed in Table 1.

TABLE 1

| Parameter | Value (MKS units) |
|---|---|
| Γ_{j,a} | 0.1 |
| τₚ | 10⁻¹² |
| Vₘ | 3 10⁻¹⁶ |
| εⱼ | 10⁻²¹ |
| αⱼ | 5 |

Semiconductor lasers also exhibit a thermal FM response arising from Joule heating and the thermo-optic effect. This effect is significant at low frequencies, from dc to typically several MHz. The thermal frequency shift is equal to:
Δωₜₕₑᵣₘₐₗ(t)=χ₁h₁[i₁(t)]²+χ₂h₂[i₂(t)]². (3)
where hᵢ represents the thermo-optic response in units of rad/s-Amp². Typically, each laser section 16 will have the same nominal thermo-optic response. Substituting in the expansion for the laser current, expressed in terms of the bias I_{bj} and small modulation Δi ⱼ, into equation (3) and linearly expanding for small Δiⱼ's, the first order expression for the thermal frequency shift becomes:
Δωₜₕₑᵣₘₐₗ(ω)=2χ₁h₁I_{b1}Δi₁+2χ₂h₂I_{b2}Δi₂. (4)

Typically, the thermal tuning response is relatively large (˜0.5 to 1 GHz/mA) and, by substitution of physical constants and realistic operating conditions, is found to be 180 degrees out-of-phase in comparison to the electronic tuning response of equation 2. There is potentially also a contribution to the FM response from a spatial hole burning effect; however, this mechanism typically exhibits a high degree of variability and in many laser devices may be smaller in magnitude than thermal and plasma effects. The use of a DFB laser exhibiting an FM response with large phase variations leads to a general instability of the feedback control system. Operating in the asymmetric, push-pull configuration disclosed next significantly reduces the thermal contribution to the FM response.

In the typical push-pull configuration of the prior art, equal and opposite modulation currents are applied to two identical laser oscillator sections in a fashion which nulls-out the electronic FM response. However, in the laser system disclosed herein, a well controlled, non-zero FM response is required. By proper selection of bias current asymmetry, a corresponding asymmetry in the modulation currents introduces a non-zero electronic FM while nulling out the thermal FM. The relation between modulation currents in sections 1 and 2, Δi ₁ and Δi₂, respectively, which cancel out the thermal FM response is given by:

$$Δ {i}_{1} = - Δ {i}_{2} ( t ) \frac{{χ}_{2} {h}_{2}}{{χ}_{1} {h}_{1}} \frac{{I}_{b 2}}{{I}_{b 1}} \qquad ( 5 )$$

Equation (5) is the general solution for the modulation current ratio which gives an electronic-only FM response, dependent on the lengths, bias currents and thermo-optic responses of the two sections 16-1, 16-2. The actual value of the FM response of DFB lasers under operating conditions satisfying the above equation is determined by solving the semiconductor rate equations. Table 2 summarizes the calculation results for various configurations, neglecting spatial hole burning effects which can be made small. By varying the ratio of modulation currents (as well as bias currents), the magnitude and sign of the FM response can be adjusted continuously within the target range of a few hundred MHz/mA. The later four examples correspond to the asymetrical push-pull configuration, which nulls out the thermal response while extending the “constant phase” bandwidth.

TABLE 2
Two Section DFB-MOPA Laser With Equal Length DFB Sections

| | | “Constant | | | Ratio of |
|---|---|---|---|---|---|
| Electronic FM | Thermal FM | Phase” | Section 1 | Section 2 | Section 1 to |
| Coefficient | Coefficient | Bandwidth | Bias Current | Bias Current | 2 Modulation |
| (MHz/mA) | (MHz/mA) | (GHz) | (mA) | (mA) | Currents |
| +200 | ˜600 | ˜0.001 | 500 | 500 | 1 |
| −101 | ˜0 | 10 | 50 | 500 | 0.1 |
| +443 | ˜0 | 10 | 500 | 100 | −5 |
| +106 | ˜0 | 10 | 500 | 250 | −2 |
| +1011 | ˜0 | 10 | 500 | 50 | −10 |

In practice, even under the condition set forth in equation 5, the thermal FM response may have a small residual component due to spatial non-uniformities in the temperature and thermo-optic coefficient across the laser oscillator sections 16-1, 16-2. To achieve a relatively constant phase for the net (thermal plus electronic) FM response (<10 degrees variation), the effective two section thermal coefficient must be reduced to a value less than 25% of the electronic value. The variation in phase and amplitude of the net FM response for various relative electronic and thermal contributions when passing through the thermal crossover frequency are summarized in Table 3. In general, the OPLL is quite sensitive to FM coefficient phase variations, but relatively insensitive to amplitude variations. A variation in phase as large as 30 degrees still provides adequate phase margin to ensure effective phase locking.

TABLE 3

| Ratio of peak magnitude of | Variation in | Variation in phase |
|---|---|---|
| electronic to thermal FM | magnitude of | of net FM |
| coefficient | FM coefficient (dB) | coefficient (degrees) |
| 6 | 1.2 | 3 |
| 5 | 3 | 7 |
| 4 | 4 | 10 |
| 3 | 6 | 15 |
| 2 | 12 | 30 |

Typical DFB lasers exhibit a Lorentzian linewidth of about 10 MHz. A phase-locking bandwidth in excess of 100 MHz is then required to provide reasonably efficient coherent combining. For these characteristics, the performance has been simulated using the two-section DFB-MOPA emitters disclosed herein. The results are summarized below in Table 4. The RMS phase error is calculated in the case of a “perfect” RO with zero linewidth and also for an RO linewidth equal to that of the LO (10 MHz). The corresponding rms phase errors are 0.04 wave (0.25 rad) and 0.089 wave (0.56 rad), respectively. This level of phase error enables two lasers to be coherently combined with greater than 95% optical efficiency. By extending this technique to thousands of lasers in an array format, a high power and high brightness semiconductor laser is produced.

TABLE 4

| | |
|---|---|
| Input Parameters | Output Parameters |

Simulation Parameter

| | |
|---|---|
| Loop Delay | 0.5 ns |
| Loop Bandwidth | 100 MHz |
| LO Laser Linewidth | 10 MHz |
| Loop Filter Type | Lead-lag |
| LO DFB Type | two section |
| LO FM Coefficient | 100 MHz/mA |

“Perfect” RO (zero linewidth)

| | |
|---|---|
| Unlocked RMS Phase Error σ | 119.5 waves |
| (1 Hz to 5 GHz) | |
| Locked RMS Phase Error σ | 0.040 wave |
| (1 Hz to 5 GHz) | |

“Typical” RO (10 MHz)

| | |
|---|---|
| Unlocked RMS Phase Error σ | 212.6 waves |
| (1 Hz to 5 GHz) | |
| Locked RMS Phase Error σ | 0.089 wave |
| (1 Hz to 5 GHz) | |

Example: Beam Combining Optics

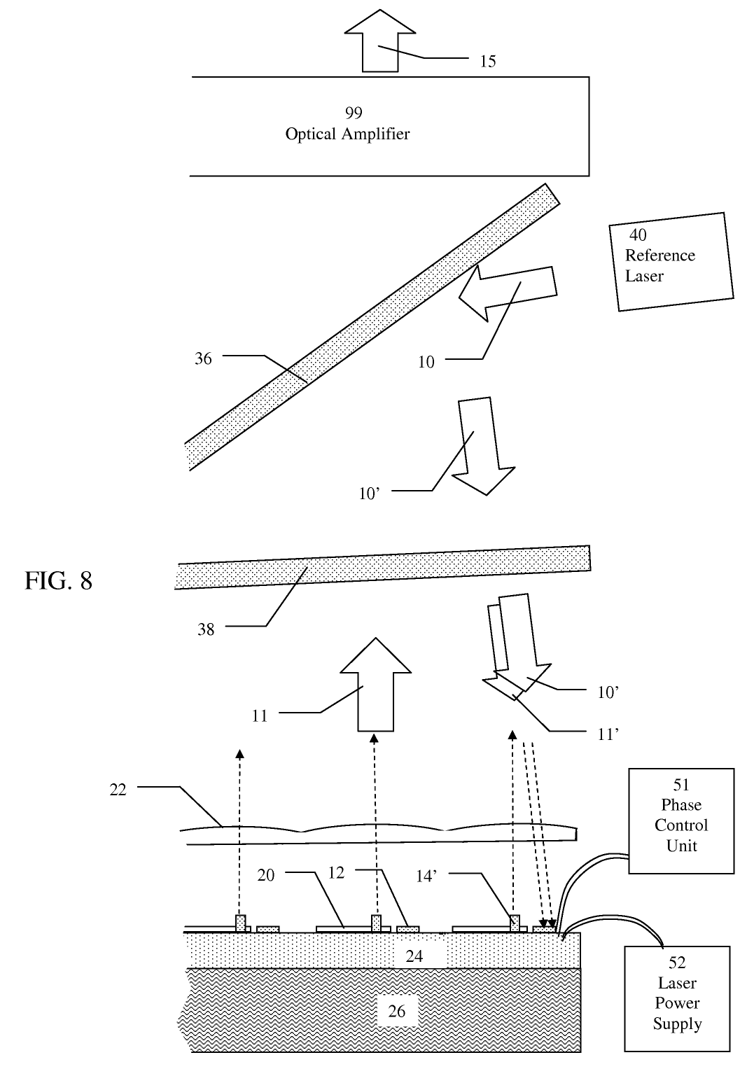

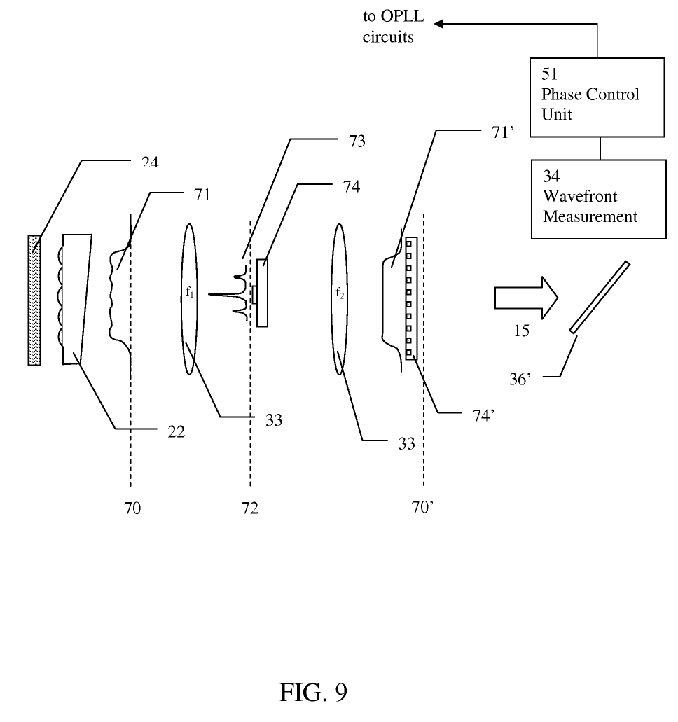

Each diode laser element 14 in the array produces a nearly diffraction limited, single spatial mode output 11 which is typically characterized by slight beam asymmetry and astigmatism. When these outputs 11-j are combined by a lens array 22, there remains a significant amplitude ripple 71 at the near field location in the back focal plane 70 of the lens array 22, as illustrated in FIG. 9. The mode distribution 73 at the far field plane 72 exhibit sidebands which degrade the resulting beam quality of the combined output beam 15 and limit the ability to focus the beam to a tight spot. In this invention, an optical system which efficiently transforms the optical mode into a mode free of amplitude and phase ripple is utilized. In the prior art, J. R. Leger et al. has disclosed a technique for “Efficient Side-lobe Suppression of Laser Diode Arrays,” in Appl. Phys. Lett. 50, 1044-1046 (1987). By shifting the phase of the central peak relative to the sidelobes at the first Fourier plane 72 by:

$${ϕ}_{o} = {cos}^{- 1} ( \frac{2 f - 1}{2 f} ) ,$$

where f is the fill factor after the lens array using phase plate 74, amplitude ripple (78 in FIG. 10-A) at plane 70′ is substantially eliminated (mode 71′) but converted to phase ripple. Therefore, the combined optical wavefront 15 requires two stages of Fourier filtering, first to covert the amplitude ripple to phase ripple (phase plate 1, 74) and finally to remove the phase ripple (phase plate 2, 74′). The combined wavefront 15 then exits the beam shaping optics at near field plane 2 (70′) free of amplitude and phase ripple. The phase 79 and amplitude 78 of the combined and shaped wavefront 15 are illustrated in FIG. 10A, where the horizontal axis 77 is the transverse axis of the beam. We disclose the use of a wavefront measurement device 43 and phase control unit 51 placed behind the beam shaping optics for analysis and control of the emitter array 24.
Example: Adaptive Wavefront Control

For many of these applications, the ability to arbitrarily set the phase of each emitter at rapid rates eliminates the need for auxiliary adaptive optical systems (e.g., deformable mirrors and micromirror arrays) and, in fact, dramatically improves the performance of existing adaptive optical systems. FIG. 10-B illustrates schematically the programmed variation of phase 79 along one axis of the output beam 15 by individually setting each emitter's (14) phase through a control voltage or current input generated by controller 51 and received by PLL circuit 20, where the horizontal axis 77 corresponds to the transverse axis of the beam. A linear variation in phase across the laser array 24 produces beam steering. A quadratic variation in phase across the array produces a variable focus. Alternately, the phase of each emitter 14 can be arbitrarily set to correct for atmospheric distortion, for example.

Shaping of the combined wavefront 15 is particularly relevant for several applications, including high power semiconductor sodium laser guide stars at 589 nm (by frequency doubling a 1178 nm diode array, for example), the management and reduction of orbital debris, lidar, and “wireless” power transfer and distribution.

In a particular example, this invention provides a new approach to sodium guide star lasers using an electrically locked laser array. The coherently locked, frequency doubled, vertically emitting high power semiconductor laser diode array provides high optical power at 589.159 nm. The semiconductor laser-based guide star offers several advantages over the prior art. First, these arrays are reliable, light-weight, compact and potentially low cost compared to present day laser guide star approaches. In addition, the high wall plug efficiency of laser diodes (60-70%) and the high doubling efficiency into the visible can produce an efficient laser source with 100's of watts of diffraction limited and single mode output power at the sodium absorption line. Furthermore, the use of coherent beam combining allows for the relative phases of the individual emitter elements 14 to be adaptively controlled at high speeds (GHz) by controller 51 to enable fast beam steering, focal shifting and adaptive wavefront compensation. This high power semiconductor laser array approach can be extended to any wavelength within the semiconductor gain region, such as the atmospheric windows of 1040 nm and 865 nm, and to powers in excess of 10's of kW.

Example: Mode Locking

In a further embodiment of this invention, semiconductor diode laser and laser arrays 24 are electronically mode-locked by configuring each laser emitter 14 as a local oscillator in an OPLL, wherein each local oscillator 14 is frequency locked to the reference laser 40 such that the difference frequency is a unique integer multiple of the pulse repetition frequency. The phases of each laser 14 are locked to be exactly in-phase, or arbitrary phase offsets can be provided. Electronic frequency and phase-locking is achieved by high-speed electronics 20 which provide both the large electrical bandwidth as well as the control and functionality necessary for stand-alone and stable mode-locked laser operation. Since the center frequency of each local oscillator 14 differs from that of the reference oscillator 40 by an integer multiple of the rf oscillator 50 frequency offset, the composite laser array output 15 has a spectrum which is a frequency comb with precise comb spacing and stable relative phase difference between each spectral component.

The electronic mode-locking of array 24 can potentially achieve in excess of 100 kW average power and 1 GW peak power from a diffraction-limited semiconductor laser diode array. The laser array is electrically and optically interfaced to an arrray of PLL circuits 20 with integrated optical detectors 12 and a reference rf oscillator 50 operating at the mode-locking pulse repetition frequency. The optical outputs of the array are transformed by beam combining optics 43 into a single near-diffraction limited spot at the output 15. The output in the locked state produces a single, high-power, mode-locked output, with a peak power given approximately by N² (where N is the number of lasers) times the average power per emitter 14.

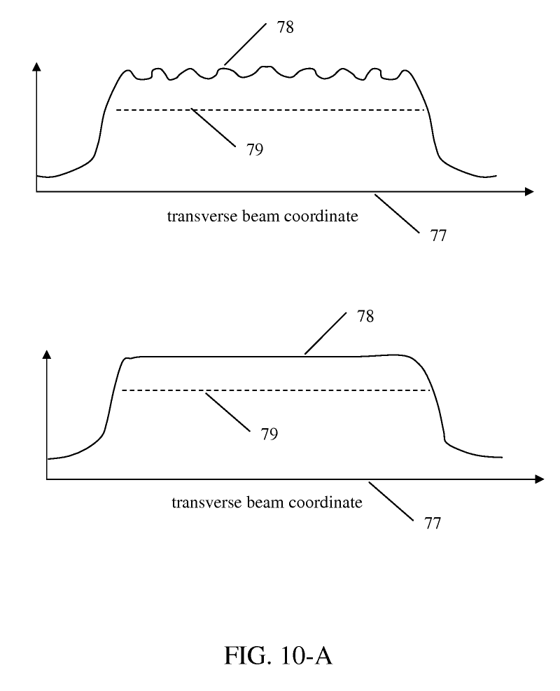

FIG. 11 illustrates a functional diagram of a series of independent OPLL circuits including independent laser local oscillators (LOs) 14 and sharing a common reference laser oscillator (RO) 40 and rf oscillator 50, where the number of independent OPLL circuits also equals N. The use of the common reference laser 40 and rf oscillator 50 is necessary to provide precise phase and frequency coherence among the N local oscillators.

In a particular example, an array of N=5000 single mode, high power (2.5 W) single mode diode lasers 14 are phase and frequency-locked to a single reference laser 40 at frequency offsets equal to integer multiples of, for illustration purposes, 20 MHz by use of an array of OPLLs with integrated optical detectors 12, loop filters 58, rf mixers 57 and multipliers 59. Each OPLL operates by optically mixing the local oscillator 14 with the reference laser 40 in an integrated photodetector 12. The optical mixing process produces a current signal containing high frequency beat components arising from a mismatch between the frequencies of the local oscillator and the reference oscillator. This beat signal is subsequently mixed at rf mixer 57 with the multiplied output of a 20 MHz rf oscillator 50. Each rf multiplier stage 59 provides a different integer multiple of the rf oscillator frequency to each mixer associated with each OPLL element. The output of the rf mixer 57 is passed through a loop filter 58 to produce an error signal suitable for driving the local laser oscillator 14. Each laser 14 functions as a current controlled oscillator (CCO) with a tuning characteristic on the order of 0.1 GHz/mA. By utilizing high bandwidth electronics, the frequency of the local oscillator can track the sum of the reference oscillator frequency and offset frequency, so that the OPLL circuit can phase and offset-frequency lock the current controlled laser to the single reference laser. This same process is applied to every laser element of the array, thereby locking all lasers to a fixed frequency comb with a given free spectral range. A coherent, pulsed output (10 ps pulse width) of high average power (10 kW), high peak power (50 MW), high beam quality (diffraction limited) and high spectral purity (<20 MHz linewidth) is thereby produced at the output of the beam combining optics 15.

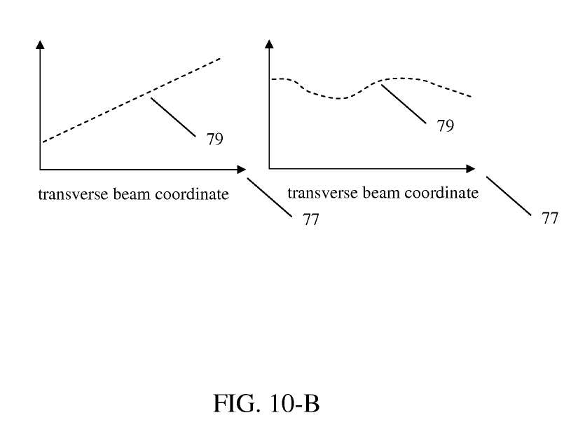

FIG. 12-top illustrates the phase-locked frequency comb produced by electrically locking each laser spectral mode 76 of amplitude 90 at frequency 91 to the reference laser 40 center frequency, plus a multiple of a fixed offset frequency using a circuit such as that illustrated in FIG. 11. Mode-locked pulses result when each laser mode 76 is in-phase with the other modes. Furthermore, by electrically controlling the amplitude 90 and phase of each laser mode 76, arbitrary temporal pulse shapes may be synthesized. The minimum pulse width is nominally equal to the pulse period (inverse repetition rate) divided by N, the number of lasers.

FIG. 12-bottom illustrates the spectrum originating from an individual local oscillator 14 wherein optical side modes of amplitude 76′, evenly distributed along frequency axis 91, are produced by modulating the single frequency optical output 11. By this method, the number of optical modes within the frequency comb can be greater than the number of independent lasers. Since the ratio of pulse-period to pulse-width is equal to the number of optical modes rather than number of lasers, the generation of additional optical modes by modulation serves to reduce with pulse width for a given number of lasers and a given pulse repetition frequency.

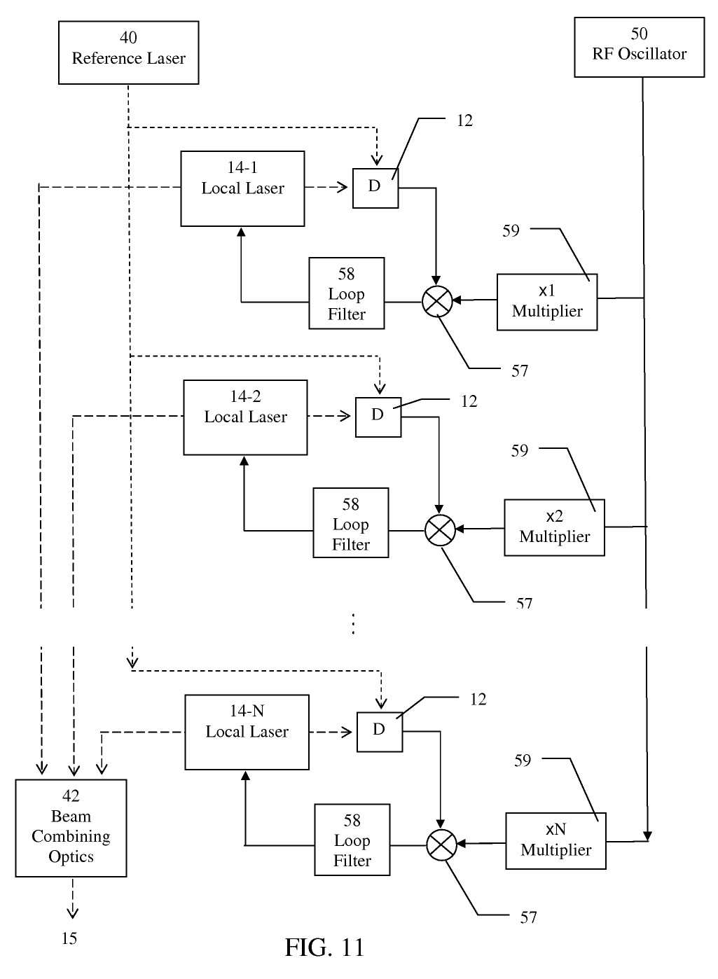

These mode locking approaches require wavelength combining optics to combine the multiple, spatially separate optical modes into a single overlapping output 15. FIG. 13 illustrates a wavelength combining optical system that combines multiple laser modes at different center frequencies into a single overlapping and co-propagating output mode 15. The diffraction-grating 30 based wavelength combining optical system merges the various frequency components of the mode locked output into a single co-propagating, co-extensive output beam. Since the frequency varies across the near field wavefront in two dimensions, a Fourier transforming lens maps the spatial variation of frequency into an angular variation of frequency at the back focal plane of the lens. One or more diffraction gratings (potentially two one dimensional gratings or a two dimensional grating) are located in the vicinity of the back focal plane of lens 33 to provide the angular dispersion necessary for all frequency components to co-propagate.

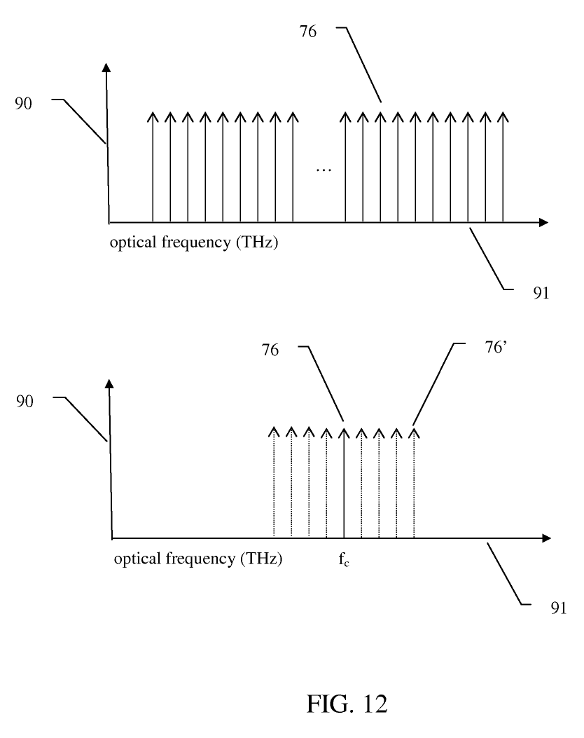

FIG. 14 illustrates a wavelength combining optical apparatus that merges multiple laser emitter outputs 11-j at different center frequencies onto a single overlapping spot 80 at a substrate plane 72. At particular instants in time, all frequency components will precisely overlap at the back focal plane of the lens, coinciding with a substrate plane 72 wherein the overlap spectral components interfere to reveal the mode locked pulses. At this substrate plane, a material can be located to undergo an ablative process, for example.

Example: Coherent Laser Power Combining

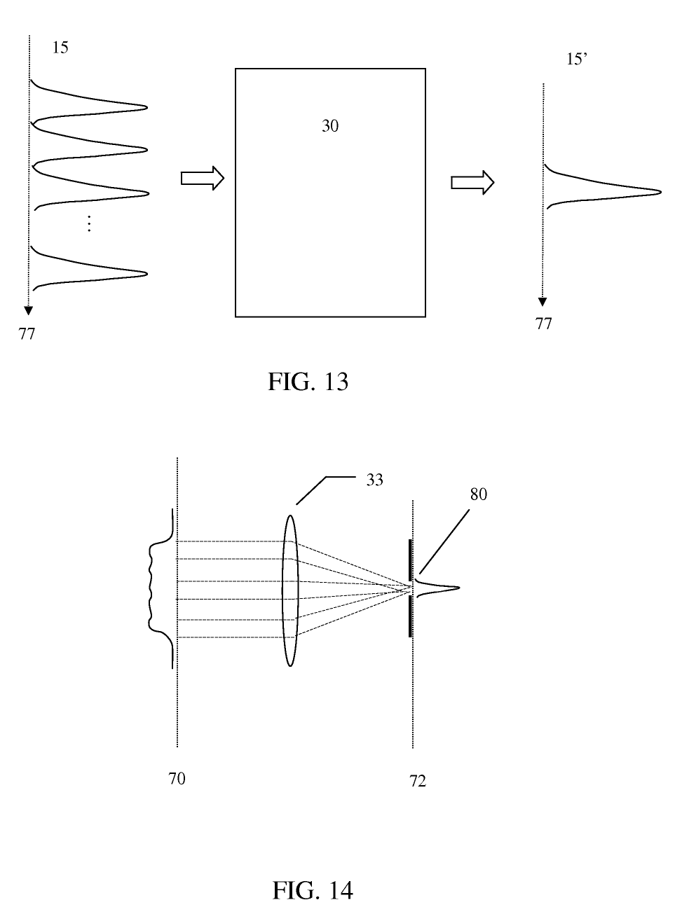

In FIG. 15, the optical power of two laser emitters 14-1, 14-2 can be coherently added into a single optical output beam 15 by combining the laser outputs using beam combiner 92 and beam splitter 92′ so that the outputs of emitters 14-1, 14-2 mix at photodetector 12 to produce an electronic beat note. This beat note is input to loop controller 20, which produces a feedback signal that drives laser 14-1 in synchronism with laser 14-2. The phase difference betweeen the optical outputs of lasers 14-1 and 14-2 is controlled by phase controller 51, which outputs a control signal to loop controller 20.

Beam combiner 92 is preferably a 50/50 fused coupler or 50/50 beam splitter which combine like polarizations. Beam splitter 92′ is a 50/50 splitter or alternately, an asymmetric tap coupler (e.g., 1/99%) which directs the majority of optical pwer to output beam 15 while tapping a small amount for detector 12. The outputs of lasers 14-1 and 14-2 are driven to be precisely phase and frequency locked, in addition to having a controllable relative phase relationship. The controllable relative phase relationship enables the maximum optical power to be produced in combined output beam 15.

Example: Linewidth Narrowing of Laser Emitter

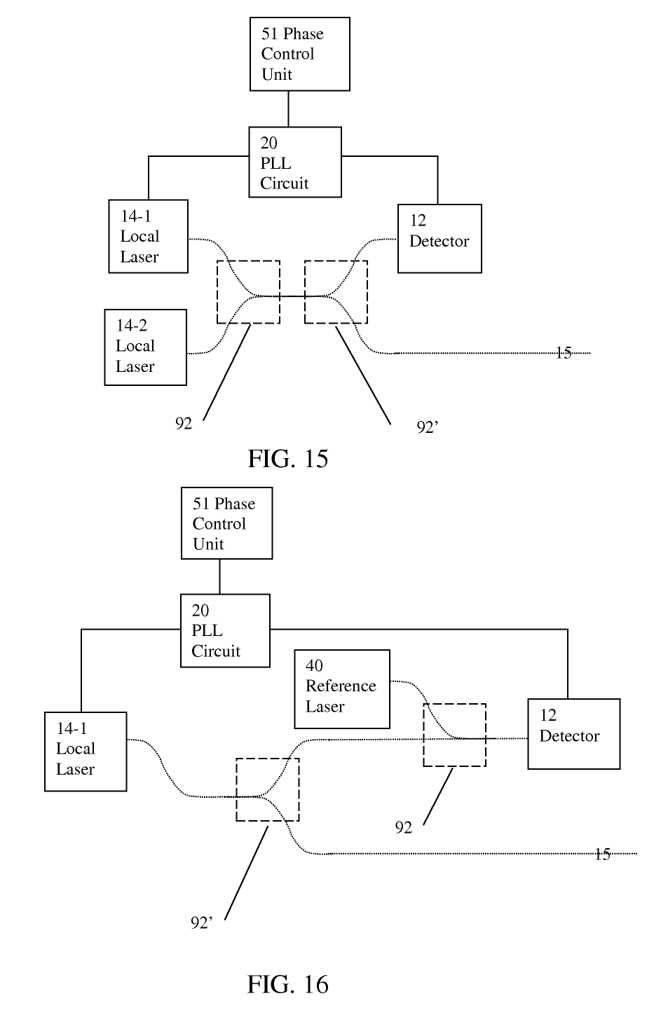

In FIG. 16, the optical power of laser emitter 14-1 and narrow linewidth reference laser 40 can be coherently combined using beam combiner 92 so the outputs of emitters 14, 40 mix at photodetector 12 to produce an electronic beat note. This beat note is input to loop controller 20, which produces a feedback signal that drives laser 14 in synchronism with reference laser 40. Reference laser 40 generally emits lower optical power than emitter 14 and exhibits narrower spectral linewidth (or reduced phase noise) . The optical output of laser 14 is split by an asymmetric beam splitter 92′, allowing the majority of optical power to pass to output beam 15 while a small fraction of its power mixes with the relatively week reference laser 40.

Beam combiner 92 is preferably a 50/50 fused coupler or 50/50 beam splitter which combine like polarizations. Beam splitter 92′ is a 50/50 splitter or alternately, an asymmetric tap coupler (e.g., 1%/99%) which directs the majority of optical power to output beam 15 while tapping a small amount for control purposes at detector 12.

The purpose of locking a high power local emitter to a low power, low noise reference laser is to transfer the low phase noise characteristics onto the high power emitter. The output beam 15 then exhibits the superior optical power characteristics of laser 14 and the superior spectral linwidth characteristics of laser 40. Typical optical power is >1 W and typical spectral linewidth is <10 KHz. The emission wavelength is typically within, but not limited to, the range of 600 nm to 2000 nm. This spectral narrowing approach is of value in applications requiring low phase noise, such as spectroscopy, sensing and coherent communications.

Example: Power Combining Based on Heterodyne Optical Phase Locking

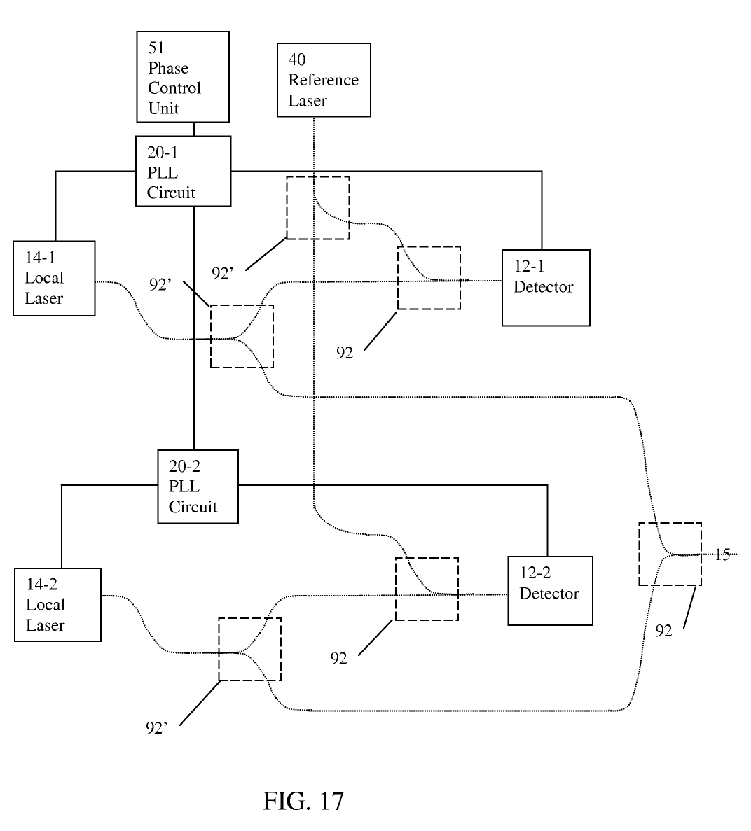

Greater design flexibility and optimized locking performance are possible by frequency and phase locking two lasers with a fixed offset frequency. However, the output power of lasers locked to within an offset frequency can not be coherently combined. To provide both the optimal performance characteristics of offset locking and provide efficient beam combining, two or more local oscillators 14-1, 14-2 are locked to within the same rf frequency offset, to a third, common reference laser 40, thereby locking the local oscillators 14-1, 14-2 to the same optical frequency (typically 100-400 THz) (FIG. 17). The precise frequency offset is generated by a shared reference rf oscillator 50 or by local rf oscillators associated with, or part of, each loop controller 20-j. Coherent summation of power is achieved by use of a phase controller 51, which provides control signals input to loop controllers 20-1 and 20-2 enabling the relative phase relationship between emitters 14-1 and 14-2 to be precisely controlled at output 15.

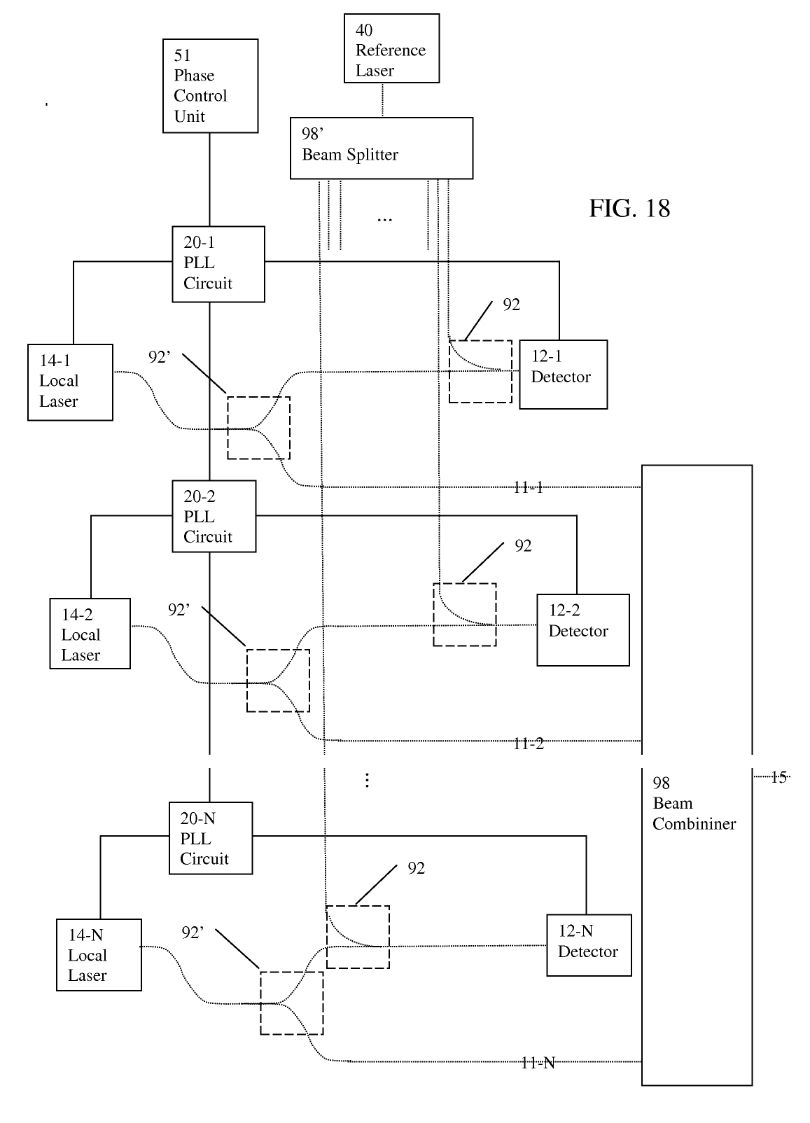

This laser system is implemented using fused fiber components, planar lightwave circuits, or bulk beam splitters to achieve the beam splitter 92′ and beam combiner 92 functionality. FIG. 18 illustrates the extension of this approach to N coherently combined emitters. In this case, the optical power of reference laser 40 is split into N outputs and distributed to each phase locked loop circuit and mixed on detectors 12-1 thru 12-N. The optical outputs 11-1 thru 11-N of each phase locked loop circuit are combined by beam combiner 90 to form an output beam 15. For heterodyne locking, the power of a shared rf reference oscillator 50 is distributed to each phase locked loop circuit, or individual rf oscillators are associated with and/or part of the N phase locked loop controllers.

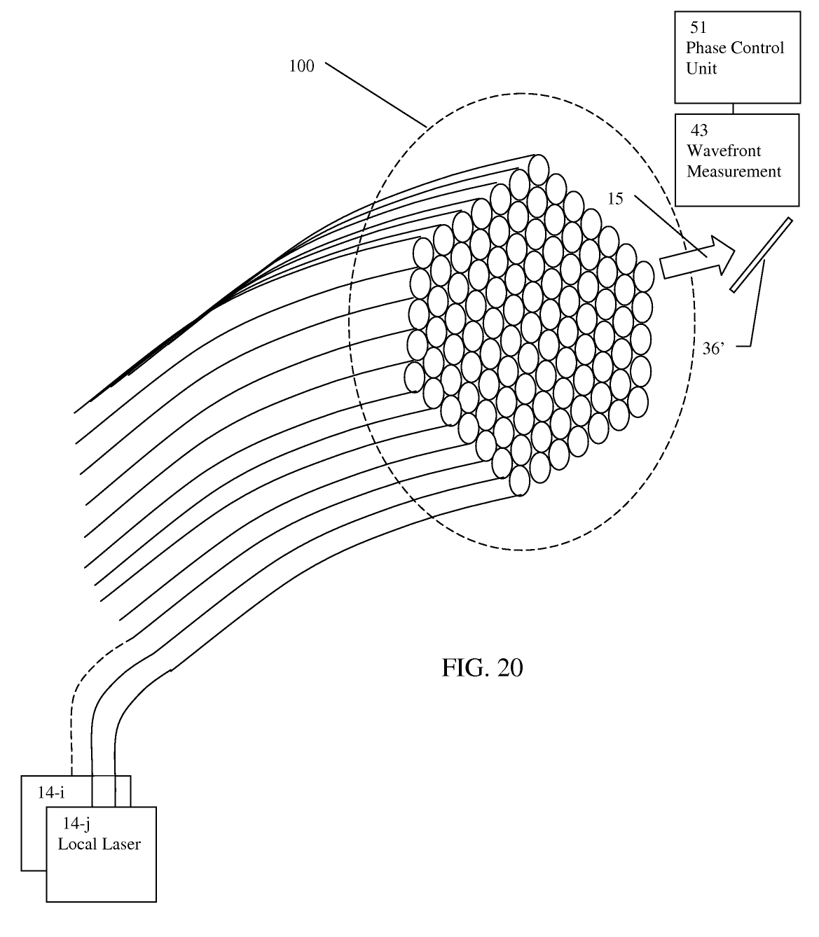

Beam splitter 98′ is typically a fused fiber or planar lightwave circuit having 16 or 32 outputs, for example. Beam combiner 98 may in addition take the form of a coherent fiber bundle 100 (FIG. 20) whose component fibers are merged at one end to form a single, closely packed output fiber array which produces an output beam 15 with an extended aperature. The optical phase of each laser element 14-j of the fiber array is adjustable by phase control circuit 51. Outputs may be phased in time to produce beam steering and active wavefront adaptation.

Example: Linewidth Narrowing of High Power Laser Emitters

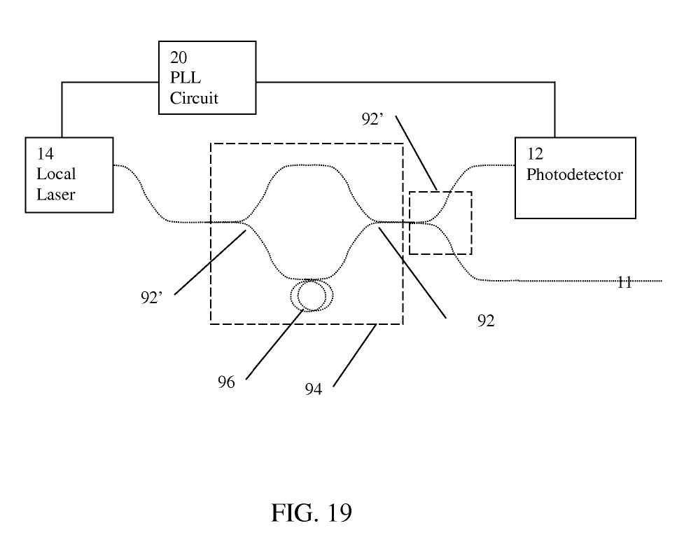

As illustrated in FIG. 19, the noise characteristics of a semiconductor laser emitter 14 can be significantly improved within the bandwidth of the feedback circuitry by detecting the laser's optical signal using an optical frequency discriminator 94 with a photodetector 12. The frequency discriminator 94 consists of, for example, a Mach-Zehnder interferometer with different delays in its two paths and is implemented using fused fiber couplers or bulk optic beamsplitters. In one embodiment, a fused fiber beam splitter 92′ is fusion spliced to a fiber beam combiner 92 with a fiber delay path 96 in one arm of the interferometer. A typical free spectral range of such an interferometer is 1 MHz to 1 GHz, selected to be a frequency range greater than the combined frequency excursion due to the laser's frequency jitter and spectral linewidth. Alternately, a frequency selective etalon consisting of a two partially reflective, plane parallel surfaces may be used. In either case, the discriminator produces an optical output whose amplitude is approximately linearly related to frequency. The detection of this signal thereby provides an electronic error signal, with amplitude proportional to frequency variation, which can be used by feedback loop 20 to stabilize the frequency of the laser 14.

In this particular example, laser emitters 14 are high power DFB lasers having an integrated tapered amplifier section which increases the output of the oscillator section(s) from 100 mW to >1 W. Note that the high speed frequency noise characteristics of the DFB laser with tapered amplifier 18 are dictated primarily by the oscillator section 16 in which the frequency selective grating resides. In addition, the oscillator section 16 can generally be FM modulated with high speeds (<1 GHz) by direct current injection into the oscillator gain section(s). Therefore, the feedback control provided by circuit 20 is applied to this oscillator section 16. The amplifier section 18 is driven with a relatively constant current independent of the feedback loop. The FM response of the amplifier section is typically restricted to relatively low frequencies (<10 KHz) for which thermal coupling between the amplifier and oscillator section enable Joule heating in the amplifier to affect the thermal distribution in the oscillator section(s).

Example: Acquisition, Phase Locking and Wavefront Control Process

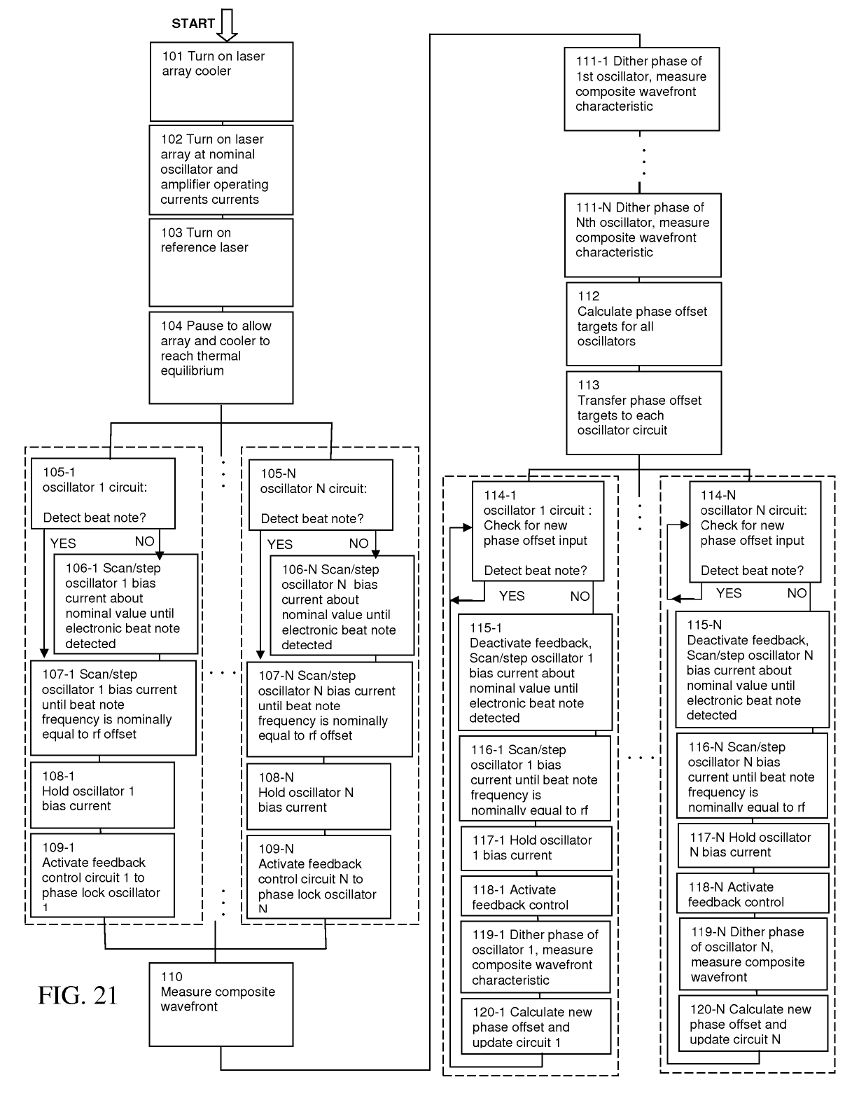

Robust and efficient phase locking of a semiconductor laser array is accomplished by performing a series of steps including frequency acquisition, phase locking and composite wavefront control steps. FIG. 21 details a flow diagram of such a process in accordance with the invention. Particular attention must be paid to the unique thermal stability issues of semiconductor lasers. The emission frequency of semiconductor lasers is a strong function of temperature (˜10 GHz/C for InGaAs DFB lasers at 1550 nm), and the temperature of the laser is a function of the drive current due to Joule heating. After powering up the lasers (steps 101-103), the temperature of all emitters much reach thermal equilibrium under nominal drive current conditions, as represented by step 104, before beginning the frequency acquisition process. Once thermal equilibrium across the array is achieved, the frequency acquisition of all emitters is performed in parallel.

The frequency acquisition process begins with the search for an electronic beat note present at the output of the transimpedance amplifier in step 105-j, where j denotes each of the emitters. All emitters undergo independent and simultaneous search processes to reduce the time to lock the entire array. The photodetector 12/TIA 55 combination typically have a bandwidth in the range of 5-10 GHz. If the initial frequency of the local laser 14-j and the reference laser 40 differ by more than this bandwidth, the beat note will lie outside of the circuit bandwidth and is not detected. In this situation, the acquisition process branches to step 106-j, wherein the bias current injected into the oscillator section(s) 16 of emitter 14-j is stepped or scanned in a search procedure until a beat note within the circuit bandwidth is detected. One such beat note detection process utilizes an rf frequency counter which counts the number of signal transitions between two threshold values in a given time period, for example. In the subsequent step 107-j, the oscillator bias current is varied to shift the nominal beat note frequency to equal that of the rf offset frequency, at which point this value of bias current is held in Step 108-j. Next, the feedback control circuit is activated to phase lock the local laser 14-j to the reference laser 40. This step 109-j is independently repeated for all local lasers in the array 24 in a parallel fashion, until all local lasers are locked to the common reference laser and made mutually coherent.

Coherent combining with a single diffraction limited composite output beam requires, in addition to phase locking, that the phases of each emitter circuit be adjusted to produce a composite beam with constant phase front. The solution wherein each emitter is locked to the same phase does not necessary lead to a constant phase front because of various imperfections in the optical path, such as optical aberrations and misalignment. Measurement step 110 is thereby incorporated to determine phase set points which accomplish the target phase front. The composite wavefront is measured, for example, by focusing the beam power through an aperture at the back focal plane of a lens while dithering the phase of each emitter independently, in a serial fashion, according to steps 111-1 thru 111-N. The phase set points which maximize the power through the aperture necessarily produce a diffraction limited output. Note that the wavefront measurement may be performed at the exit of the laser, can be remotely located, or can be performed on the light reflected from a distant target, for example. In this latter case, the phase set points may be programmed to correct for atmospheric aberrations or thermal distortions, for example. The phase set points can potentially be updated at high refresh rates to correct for dynamic aberrations or to accomplish beam stearing and/or focusing.

Slight temperature or acoustic variations, for example, can potentially cause the emitter circuits to lose phase lock. As a consequence, each emitter circuit continuously monitors the presence of a beat note in steps 114-1 through 114-N during normal operation. Should the beat note shift outside the bandwidth of the detection circuitry, a step/scan process (steps 115-j through 117-j) to re-acquire is automatically initiated for the particular emitter(s) out-of-lock. This is followed by the reactivation of feedback control 118-j to phase lock the jth emitter. Once locking is restored, the associated phase offset may need to be recomputed based on the composite wavefront measurement. In step 119-j, the wavefront is measured while varying the phase of emittter j. The phase control unit 51 processes this data to calculate and update the emitter with its new phase setpoint 120-j.

The determination of phase offsets can potentially be performed in parallel by associating the optical phase of each emitter with a unique dither frequency in step 119-j. This has the benefit that frequency acquisition can be performed more quickly, since rf spectral analysis decomposes the composite wavefront measurement into independent contributions from each emitter. This enables real-time adaptation of the composite wavefront's phase and amplitude distributions.

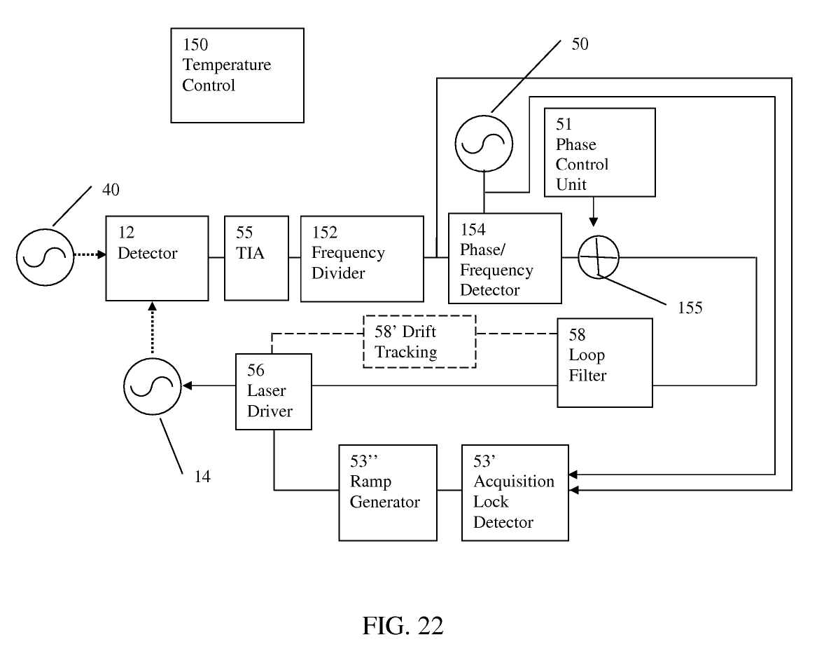

FIG. 22 illustrates a system level diagram of the optical phase locked loop and associated circuitry to realize the process steps outlined in FIG. 21. First, the temperature of the local laser 14 and the reference laser 40 are precisely controlled by temperature control unit 150. The PLL utilizes heterodyne locking, wherein the reference laser 40 and local laser 14 frequencies are locked with an offset frequency. The offset frequency is produced by a radio frequency (RF) signal generator 50 distributed to all emitter circuits. This architecture has potential advantages over homodyne PLL architectures, wherein the two lasers are locked without frequency offset. Offset locking provides for greater functionality and higher performance by incorporating the phase-frequency detector 154. To lock the frequencies and phases of all emitters 14-j to the same values, it is advantageous to utilize a third-order PLL.

Once the local laser's frequency is within the PLL locking range, the main loop with fast response will take over from the acquisition loop and acquire the lock. The acquisition loop is disengaged under locked conditions. The frequency of the beat noise signal produced by the TIA 55 may potentially be divided by frequency divider circuit element 152. Loop filter 58 is preferably of the charge pump type. A portion of loop filter 58 may be optionally input into a drift tracking circuit 58′, which includes, for example, an electronic integrator preceeded by an offset circuit. This low frequency circuit can be implemented by standard op amp/transister circuits. The drift tracking circuit is output to the laser driver 56, such that the loop tracks slow thermal drifts. Thermal drifts play a significant factor because the frequency of typical semiconductor laser emitters drift by 1 MHz per mK. Appropriate phase offsets are provided by phase control unit 51 and summed by element 155 with the output of phase/frequency detector 154.

An acquisition lock detector 53′ and ramp generator 53″ are used for the initial frequency acquisition process. The use of an offset locking approach facilitates the re-acquisition process if the frequency offset (e.g., 1 GHz) is larger than the typical frequency jump event that unlocks the loop (e.g., 100 MHz) because the frequency change of the beat note provides, unambigously, the frequency of the local oscillator. In homodyne locking, the beat note does unambigously determine whether the local oscillator is higher or lower in frequency than the beat note.

The acquisition loop is critical in this laser array system since the initial frequencies of the multiplicity of laser pairs potentially differ by more than the bandwidth of the optical detector 12 and/or the transimpedance amplifier 55. This requires that the bias current of the local laser 14 be scannned until a beat note is detected. The ramp generator 53-2 output produces a bias current ramp at the local laser 14 through the laser driver 5, which tunes or chirps the laser frequency until the beat note frequency is detected and equal to the rf offset frequency. The acquisition loop is engaged in the start-up phase, and is reactivated if a laser loses lock due to temperature changes, laser mode hopping or other perturbations.

To summarize this invention, phase locked laser arrays and various laser designs and OPLL circuit implementations are disclosed. The extension of this OPLL approach to the array format leads to numerous applications in the area of high power lasers and optical phased array lasers. Examples of the use of this technique to linewidth narrowed semiconductor lasers has been disclosed. Those skilled in the art will readily observe that numerous modifications and alterations of the device may be made while retaining the teachings of the invention. Accordingly, the above disclosure should be construed as limited only by the metes and bounds of the appended claims.

1. A semiconductor laser array comprising:
a multiplicity of single temporal mode lasers disposed in a plane and emitting substantially perpendicular therefrom; the lasers each having at least one gain section for controlling the laser frequency;
a reference laser emitting a beam;
a multiplicity of error feedback circuits on the array for providing phase difference signals representing the phase relation between individual lasers and the reference laser; and
control circuits responsive to the phase difference signals for providing individual current injection signals to the gain sections of the different lasers.

2. An array as set forth in claim 1 above, including optics disposed in the paths of emissions from the individual lasers to direct emissions to an error feedback circuit, corresponding to the individual laser the error feedback circuits each including a detector device for mixing the individual directed emission with the reference laser emission.

3. An array as set forth in claim 2 above, including a substrate disposed adjacent to the laser plane and supporting the lasers in a distributed geometry the lasers each having at least one gain section joining a diverging amplifier section and include a terminal deflector directing the emission therefrom into a direction perpendicular to the plane and substantially parallel to the other emissions.

4. A high power laser array providing a combined power beam from a given plane, comprising:
a substrate defining the given plane;
a plurality of semiconductor lasers distributed on the substrate, and each emitting parallel to a common direction;
a plurality of semiconductor control circuit dies interspersed on the substrate among the lasers for providing error control signals to the lasers;
a plurality of photo detectors interspersed on the substrate among the lasers and the control circuit dies, and each coupled to a different control circuit;
a reference laser disposed to direct a reference beam on each of the photo detectors;
an optics system disposed adjacent the substrate in the paths of the emissions for directing a small fraction of the laser emissions on the photodetectors individual to the different lasers, the photodetectors providing mixed frequency signals to the associated control circuits.

5. A multiple laser system for providing a combined high power laser beam, comprising:
a plurality of semiconductor lasers mounted in a common plane to direct like frequency emissions in parallel substantially normal to the plane, the lasers being phase controllable by individual injection currents;
a plurality of phase control circuits, each one providing a different injection current to a different laser in response to an error signal;
a reference laser directing a reference beam;
a plurality of phase error signal generators coupled individually to the phase control circuits, each including a different optical pickoff sampling coextensive laser emission from a different individual laser and from the reference beam to derive an error signal for the phase control circuits, and an optical system for combining the different emissions from the plurality of lasers to provide a light power laser beam.

6. A laser combination providing high optical power and being controllable in frequency, comprising:
two serially coupled distributed feedback oscillator sections each individually responsive to a different bias current;
a reference optical signal generator providing a reference frequency signal;
a local optical signal generator providing a local frequency signal output from the power amplifier section;
a detector circuit for providing a frequency difference signal from the reference and local frequency signals, and
a bias current source responsive to the detector circuit and coupled to the oscillator sections, the bias current source including a pair of bias current injector sections, each coupled to a different oscillator section and providing modulation currents thereto in a selected ratio.

7. A laser combination as set forth in claim 6 above, wherein the bias current source drives the oscillator sections asymmetrically in push-pull relation.

8. A laser combination as set forth in claim 7 above, wherein the oscillator sections are of equal length, the asymmetric push-pull relation is established by the bias currents, and further including an electrically pumped optical amplifier section in series with the oscillator sections.

9. A laser combination as set forth in claim 6 above, wherein the bias circuit source includes a current amplifier and an inverting amplifier, and wherein the output of one of the bias current injector sections is summed with the output of the current amplifier and the output of the other current injector section is summed with the output of the inverter amplifier after receiving the current amplifier output

10. A laser combination as set forth in claim 6 above, including a circuit for offsetting the optical frequency of the laser by a predetermined frequency value, comprising in addition a radio frequency oscillator providing a signal at the offset frequency; a mixer for combining the offset frequency with the frequency difference signal, and a circuit for adjusting the bias current to one of the oscillator sections until the optical frequency lies within the loop bandwidth.

11. A single frequency semiconductor laser element characterized by high output optical power and controllable frequency modulation response, comprised of:
a first gain section including a distributed grating in a waveguide of uniform cross section having a first electrical input contact;
a second gain section including a distributed grating in a waveguide of uniform cross section having a second electrical input contact;
wherein all electrical inputs consist of bias currents, and additionally the first and second electrical inputs further include first and second modulation currents summed thereto, respectively, in which the first and second modulation currents are of opposite sign.

12. A laser device in accordance with claim 11 above, wherein the laser is further comprised of a third gain section in a waveguide of non-uniform cross section having a third electrical input contact, the output optical power is in the range of 1-10 Watts, the single frequency is in the range of 400 nm to 2000 nm, the first and second gain sections are nominally 100 to 2000 microns in length, and the third gain section is nominally 500 to 5000 microns in length.

13. A laser device in accordance with claim 11 above, wherein the semiconductor laser waveguide lies in a substrate plane, and wherein the direction of output optical power is substantially normal to the plane of the substrate.

14. A laser device in accordance with claim 12, wherein the output optical power is directed out of the plane of the waveguides by a deflecting facet or diffraction grating in after the third gain section.

15. A semiconductor laser device in which the free running laser phase noise is reduced by high bandwidth electronic control, comprised of:
a semiconductor laser whose optical output emission frequency is a function of the input drive current with a relatively constant phase characteristic over the high bandwidth;
a frequency discriminator into which the optical output is launched;
a light responsive detector at the output of the frequency discriminator producing an electronic signal characteristic of laser frequency noise, and
a compact loop control integrated circuit which transforms the electronic signal into a modulated drive current of high bandwidth injected into the semiconductor laser, thereby reducing the phase noise of the semiconductor laser.

16. The semiconductor laser device in accordance with claim 15, wherein the semiconductor laser exhibits a modulation response with the relatively constant phase characteristic, the modulation response substantially produced by changes in spatial hole burning due to changes in input drive current.

17. The semiconductor laser device in accordance with claim 15, wherein the semiconductor laser includes a tapered amplifier section and two DFB oscillator sections, and exhibits a modulation response with the relatively constant phase characteristic by driving the two DFB oscillator sections in an asymmetric push-pull relationship.

18. The semiconductor laser device in accordance with claim 15, wherein the frequency discriminator comprises an unbalanced fiber optic interferometer with a free spectral range of 1 MHz to 10 GHz.

19. The semiconductor laser device in accordance with claim 15, wherein the laser phase noise is characterized by a linewidth, and the reduced linewidth is at least ten times narrower than the free running linewidth.

20. The semiconductor laser device in accordance with claim 19, wherein the free running linewidth is nominally greater than 500 KHz and the reduced linewidth is nominally less than 50 KHz.

21. A system of optical fiber coupled semiconductor lasers whose output power is coherently combined, comprising:
a multiplicity of fiber coupled semiconductor local lasers whose outputs are individually split by tap couplers to a thru path and a monitor path;
a reference laser whose output power is split into branches, each branch combined with the monitor path of the semiconductor laser by fiber couplers;
a multiplicity of photodetectors which receive optical signals from local lasers and reference laser by way of tap couplers and fiber couplers;
a multiplicity of electronic feedback circuits receiving additional control signals from the phase control unit,
whereby each photodetector produces an electronic beat signal at a difference frequency between the local laser and reference laser which is directed into the electronic feedback circuit, wherein the electronic feedback circuit drives the local lasers such that they are substantially phase and frequency locked, with relative phases determined by the phase control unit.

22. A laser system in accordance with claim 21, wherein the phase control unit measures the optical characteristics of the combined optical output beam and controls the nominal phase of each emitter to maximize the optical power of the combined beam.

23. A laser system in accordance with claim 21 wherein the reference laser emits at an optical frequency which is offset from the local lasers by 500 MHz to 5 GHz.

24. An optical system for multiplying the brightness of a laser source, including a phase control unit to coherently combine the outputs of a multiplicity of lasers into a composite wavefront characterized by a brightness larger than the brightness of individual lasers, comprised of:
a lens array forming a composite wavefront;
a beam splitter disposed to transmit a substantial fraction of power of the composite wavefront;
a first lens and a binary phase plate, located in the back focal plane of the first lens to delay the zero spatial frequency component of the beam relative to the adjacent sidelobes residing at a spatial frequency corresponding to the physical spacing between lasers;
a second lens and a second phase plate, the second lens being located in the back focal plane of the second lens to provide a substantially periodic phase variation complementary to the phase variation of the composite wavefront at a spatial frequency related to the physical spacing between lasers,
whereby the phase control unit sets the phases of the outputs of the multiplicity of lasers to shape the amplitude and/or phase profile of the composite wavefront.

25. An optical system for laser brightness multiplication including a phase control unit to coherently combine the outputs of a multiplicity of lasers into a composite wavefront characterized by a brightness larger than the brightness of individual lasers, comprised of:
a multiplicity of lasers;
a coherent fiber bundle with multiple fiber strands and a single polished bundle endface, the strands individually spliced to the multiplicity of laser coupled optical fibers,
whereby the composite wavefront is emitted from the bundle endface and the phase control unit sets the phase of the outputs of the multiplicity of lasers to shape the composite wavefront.

26. A system for providing high power electromagnetic wave patterns with predetermined wavefronts comprising:
a plurality of current controlled laser emitters directing output beams in parallel contiguity from a predetermined plane;
a plurality of individual current control circuits, each coupled to a different one of the emitters;
a reference signal source with an output beam directed substantially parallel to the output beams of the current controlled laser emitters;
a number of bias signal generators, each individually responsive to the frequency of a different emitter and the frequency of the reference signal source and coupled to a different one of the plurality of current control circuits, and
a controller coupled to each of the current control circuits for varying the emissions from individual emitters in an integrated manner to vary the beam wavefront.

27. A system as set forth in claim. 26 above, wherein the current control circuits each include an electro-optical phase locked loop, optical detectors responsive to the mixing of individual emitter frequencies and the reference frequency, and integrated circuits for varying at least one of the frequency and phase of each emitted beam to provide a predetermined wavefront.

28. A system as set forth in claim 26 above, wherein the individual current control circuits further include an electronic oscillator frequency source to offset the emitter frequency to a frequency different from the reference frequency.

29. A system as set forth in claim 28 above, wherein the circuit for each emitter includes an acquisition circuit coupled to the local oscillator and the reference frequency source, and an optical beam splitter circuit for combining the two.

30. A system as set forth in claim 29 above, wherein the local oscillator frequency sources are offset from each other by an integer multiple of a predetermined frequency.

31. A system as set forth in claim 29 above, wherein the controller varies the relative phases of the emissions for beam steering.

32. A system as set forth in claim 26 above, wherein the laser emitters have frequencies outside the visible spectrum and wherein the system further includes non-linear optical frequency doubling elements coupled to the emitters for doubling the frequency of the emitted beams into the visible wavelength range.

33. A system as set forth in claim 26 above, wherein the system is designed to function as a laser guide star for energy directing and/or imaging purposes, and includes a system for measurement of the effect of local atmospheric distortions on the wavefront and control circuits responsive to the measurement for adaptive wavefront correction.

34. A multi-emitter optical transmission system for combining individual parallel mono-frequency beams into a high powered beam, comprising:
a two dimensional matrix of current controlled mono-frequency emitters transmitting diverging parallel beams with predetermined polarization, the emitters being variable in response to individual control signals to emit at controllable frequencies within a selected frequency range;
a reference signal source transmitting a counter-propagating reference beam toward the matrix of emitters;
a polarizer matrix disposed across the paths of the emitted beams, the polarizer matrix including a pattern of apertures positioned to allow passage of the diverging beams therethrough, the direction of transmission polarization being perpendicular to the polarization of the emitted beams;
a plurality of photodetectors disposed throughout the plane of the emitters and individually associated with different emitters;
a matrix of lenslets disposed substantially parallel to the plane of the emitters and configured to collimate the diverging beams;
a plurality of pick-off mirrors disposed at a slight angle to the plane of the emitters and configured to reflect individual emitter power onto the plurality of photodetectors that is substantially equivalent to the power received from the reference beam thereat, and
a plurality of optical phase lock loop circuits, each responsive to a different photodetector responsive to a different emitter, and coupled to provide current control signals for the responsive emitters.

35. A system set forth in claim 34 above, wherein the lenslets have a toric configuration, and wherein the system further includes a matrix of baffle elements for isolating emitters from cross transmissions.

36. A system as set forth in claim 34 above, wherein the pick-off mirror is positioned and configured to deflect between 0.01% to 1% of the emitter transmissions onto the photodetectors, and wherein the system also includes Fourier filters disposed in the path of the emitted beams for substantially eliminating amplitude and phase ripple, in the emanations from the emission.

37. In a multiple beam emitting system wherein the beams are from mono-frequency emitters having coherent characteristics and the beams diverge along substantially parallel axes from a common plane, a system for forming a composite beam into a predetermined wavefront comprising:
an array of lenslets disposed across the paths of the emitted beams for collimating the beams;
a first optical filter disposed in the path of the beams after the lenslet array for suppressing periodic amplitude ripple on the composite beam transmitted by the lenslets;
a second optical filter disposed in the path of the composite beam after the first optical filter for suppressing phase ripple in the beam, and
a phase control unit for individually controlling the phases of the multiple beams.

38. A system as set forth in claim 37 above, wherein the first and second optical filters are phase plates etched in a substantially transparent substrate such as fused silica or quartz.

39. A laser system which combines beams from multiple laser oscillators having current controlled gain sections and emitting along parallel paths, comprising:
a common reference signal source;
a plurality of difference measuring circuits, each responsive to the signal from a different laser oscillator and the common laser reference signal for indicating a timing difference therebetween;
a plurality of optical phase locked loops, each coupled to one or more current controlled gain sections of a different laser oscillator and responsive to the timing difference indication for the associated laser oscillator, and
a plurality of timing offset circuits coupled to the optical phase locked loops for locking at least some of the laser oscillators to signals offset in frequency from the laser reference signal.

40. An array as set forth in claim 39 above, wherein the timing offset circuits receive electronic oscillator inputs whose frequencies vary in integer relationships to one another.

41. An array as set forth in claim 39 above, wherein the optical phase locked loops include acquisition circuits for adjusting signal differences until an appropriate control range is established.

42. An array as set forth in claim 39 above, wherein the difference measuring circuits include photo detectors providing beat signals responsive to timing differences between the applied signals.

43. The method of coherently combining the beams from a plurality of beam emitting semiconductor lasers propagating substantially in parallel from a substrate plane to form a predetermined composite wavefront, the lasers oscillating at controllable frequencies, comprising the steps of:
equilibrating the temperature of the emitting lasers at the substrate plane;
propagating a frequency reference signal for all lasers;
providing separate controllable local oscillator frequencies at predetermined offsets from the reference frequency;
comparing each emitter frequency to respective reference frequency to provide frequency beat notes;
individually locking the different emitting lasers to predetermined offset frequencies dependent on the existence of frequency beat notes;
measuring the composite wavefront, and
individually phase locking the emitting lasers relative to the phase of the reference frequency in a pattern determining a composite coherent wavefront.

44. A method of coherently combining beams from a multiplicity of semiconductor current-controlled laser emitters in physical contact with a common substrate, comprising the steps of:
driving the laser emitters at their nominal operating current;
controlling the temperature of the common substrate to equilibrate the temperatures of the emitters;
supplying a reference frequency;
supplying a plurality of local oscillator frequencies at offset values;
comparing the timing relationship between the different laser emitters and the local oscillator frequency;
individually varying the current control signal into the laser emitters in parallel fashion until optical interference signals are detected within a comparison bandwidth;
fine tuning the different control currents in parallel fashion until the frequency of each emitter signal is nominally equal to a target offset frequency for that laser;
modulating the frequency of each emitter in accordance with the optical interference signals;
measuring the wavefront to determine phase set points for a target phase front by independently varying the phases of the local oscillators;
setting the phases of the emitted frequencies in accordance with the measurements, and
repeating the tuning and phase lock sequences if the emitter frequency shifts outside of the comparison bandwidth.
